(19) United States
(12) Patent Application Publication
(10) Pub. No.: US 2026/0059942 A1
(43) Pub. Date: Feb. 26, 2026

(54) ELECTRONIC DEVICE AND MANUFACTURING METHOD OF DISPLAY DEVICE

(71) Applicant: Samsung Display Co., Ltd., Yongin-si (KR)

(72) Inventor: YOUNGJAE JEON, Yongin-si (KR)

(73) Assignee: Samsung Display Co., Ltd., Yongin-si (KR)

(21) Appl. No.: 19/241,888

(22) Filed: Jun. 18, 2025

(30) Foreign Application Priority Data
Aug. 22, 2024 (KR) 10-2024-0112778

(51) Int. Cl. H10K 59/122; H10K 59/12; H10K 59/131

(52) U.S. Cl. CPC H10K 59/122; H10K 59/1201; H10K 59/131

(57) ABSTRACT

An electronic device includes a circuit element layer disposed on a base substrate and including a power line, and a display element layer including an emission area and a non-emission area. The display element layer include a pixel defining film having an emission opening portion corresponding to the emission area and an opening portion overlapping the non-emission area, a connection electrode having at least a portion exposed by the opening portion, a light emitting element including a first electrode having at least a portion exposed by the emission opening portion, and a second electrode overlapping the emission area and the non-emission area, and a first separator which is disposed on the connection electrode and cuts the second electrode. A portion of the second electrode, which is cut by the first separator, is in contact with the connection electrode in the non-emission area.

### CROSS-REFERENCE TO RELATED APPLICATION(S)

This application claims priority of Korean Patent Application No. 10-2024-0112778 under 35 U.S. C. § 119, filed Aug. 22, 2024, the entire contents of which are incorporated herein by reference.

### BACKGROUND

The disclosure relates to an electronic device and a method for manufacturing the display device.

Particularly, the disclosure herein relates to an electronic device which includes a light emitting element including an emission unit disposed, in common, in adjacent emission areas, and a power line electrically connected to a common electrode of the light emitting element.

Multimedia display devices such as televisions, mobile phones, tablet computers, navigation devices, game consoles, or wearable devices, may include display panels which display images. In the display panels, a so-called self-emissive display element is used in which a light emitting material including an organic compound, a quantum dot, or the like in an emission layer disposed between electrodes facing each other emits light to accomplish display.

As a demand for high definition of multimedia electronic devices increases, an arrangement gap between adjacent light emitting elements is decreased so as to exhibit high-resolution display quality, and accordingly, leakage emission affecting luminous characteristics of an adjacent pixel may be generated to decrease the display quality.

Display devices including organic light emitting elements among light emitting elements receive attention as next-generation display devices owing to their merits such as wide viewing angle, fast response speed, and low power consumption. However, with the large scale of the display devices, there are a decrease in stability of voltages supplied according to regions, and accordingly, nonuniformity in luminance.

### SUMMARY

The disclosure provides a display device with improved reliability of an electrical connection structure of a common electrode and a power line, and reduced leakage current between adjacent pixels.

The disclosure also provides a method for manufacturing a display device capable of electrically connecting a common electrode and a power line to each other without laser drilling.

However, embodiments are not limited to those set forth herein. The above and other embodiments will become more apparent to one of ordinary skill in the art to which the disclosure pertains by referencing the detailed description of the disclosure given below.

An embodiment provides a display device including a base substrate, a circuit element layer disposed on the base substrate and including a power line which receives a power voltage, and a display element layer disposed on the circuit element layer and including an emission area and a non-emission area adjacent to the emission area. The display element layer may include a pixel defining film including an emission opening portion overlapping the emission area and an opening portion overlapping the non-emission area, a connection electrode overlapping the non-emission area, including at least a portion exposed by the opening portion, and electrically connected to the power line, a light emitting element including a first electrode including at least a portion exposed by the emission opening portion, an emission unit disposed on the first electrode, and a second electrode disposed on the emission unit and overlapping the emission area and the non-emission area, and a first separator which is disposed on the connection electrode and cuts the second electrode. A portion of the second electrode, which is cut by the first separator, may be in contact with the connection electrode in the non-emission area.

In an embodiment, in the display device, the circuit element layer may further include an insulating layer disposed on the power line, and the connection electrode may be connected to the power line through a contact hole defined in the insulating layer.

In an embodiment, the portion of the second electrode, which is cut by the first separator, may overlap the first separator in a plan view.

In an embodiment, the opening portion may entirely expose the connection electrode.

In an embodiment, the first separator may have an undercut shape.

In an embodiment, the first separator may include a first portion, and a second portion disposed below the first portion and in contact with the connection electrode, and a width of the first portion in a direction may be greater than a width of the second portion in the direction.

In an embodiment, the display device may further include a first dummy pattern disposed on the first separator, and a second dummy pattern disposed on the first dummy pattern. The first dummy pattern and the emission unit may include a same material, and the second dummy pattern and the second electrode may include a same material.

In an embodiment, the emission unit may overlap the emission area and the non-emission area, and a portion of the emission unit may be disposed between the connection electrode and the second electrode in the non-emission area.

In an embodiment, the display device may further include a first dummy pattern disposed on the first separator, and a second dummy pattern disposed on the first dummy pattern. The first separator may include a first portion, and a second portion disposed below the first portion and in contact with the connection electrode, and the second dummy pattern may cover a first side surface of the first separator, which defines the first portion.

In an embodiment, the second dummy pattern may further cover a portion of a second side surface of the first separator, which defines the second portion.

In an embodiment, the first separator may include a first portion, and a second portion disposed below the first portion and in contact with the connection electrode, and a width of the first portion in a direction may be greater than a width of the second portion in the direction. The portion of the second electrode, which is cut by the first separator, may overlap the first portion and be spaced apart from the second portion in the direction, and be in contact with the connection electrode.

In an embodiment, the first portion and the second portion may have a shape of one body.

In an embodiment, the display device may further include a second separator disposed to be spaced apart from the first separator in a plan view, the emission unit may overlap the emission area and the non-emission area, the light emitting element may include a first light emitting element, and a second light emitting element spaced apart from the first light emitting element in a direction, and the second separator may be disposed between the first light emitting element and the second light emitting element and cut the emission unit in the non-emission area.

In an embodiment, the emission unit may include a first emission structure, a second emission structure, a third emission structure, and a fourth emission structure, each of which includes an emission layer and which are stacked in a thickness direction, and first, second, and third charge generation layers, each of which is disposed between adjacent emission structures among the first emission structure, the second emission structure, the third emission structure, and the fourth emission structure.

In an embodiment, at least one of the first emission structure, the second emission structure, the third emission structure, or the fourth emission structure, and at least one of the first, second, or third charge generation layer may be cut by the first separator.

In an embodiment, a method for manufacturing a display device includes forming a power line on a base substrate, forming a connection electrode electrically connected to the power line on the base substrate, forming a first electrode on the base substrate, forming a pixel defining film including an opening portion, which exposes at least a portion of the connection electrode, and an emission opening portion which exposes at least a portion of the first electrode, forming a separator on the connection electrode, forming an emission unit overlapping the first electrode, the connection electrode, the pixel defining film, and the separator, and forming a second electrode overlapping the first electrode, the connection electrode, the pixel defining film, and the separator. The emission unit may be cut by the separator, the second electrode may be cut by the separator, and a portion of the second electrode, which is cut by the separator, may be in contact with the connection electrode.

In an embodiment, the connection electrode and the first electrode may be formed through a same process.

In an embodiment, the portion of the second electrode, which is cut, may overlap the separator.

In an embodiment, in the forming of the separator, a first portion and a second portion having a shape of one body together with the first portion may be formed, and a width of the first portion in a direction may be formed to be greater than a width of the second portion in the direction.

In an embodiment, in the forming of the separator, a first dummy pattern patterned by the separator and a second dummy pattern disposed on the first dummy pattern may be formed, the first dummy pattern and the emission unit may be formed through a same process, and the second dummy pattern and the second electrode may be formed through a same process.

### BRIEF DESCRIPTION OF THE DRAWINGS

The accompanying drawings are included to provide a further understanding of the invention, and are incorporated in and constitute a part of this specification. The drawings illustrate embodiments and, together with the description, serve to explain principles of the invention. In the drawings:

FIG. 1A is a schematic perspective view of a display device according to an embodiment;

FIG. 1B is a schematic cross-sectional view of a display device according to an embodiment;

FIG. 2 is a schematic plan view of a display panel according to an embodiment;

FIG. 3 is an enlarged schematic plan view of a portion of a display area of a display device according to an embodiment;

FIG. 4 is a schematic cross-sectional view of a portion of a display device according to an embodiment;

FIG. 5 is a schematic cross-sectional view of a light emitting element according to an embodiment;

FIG. 6 is a schematic plan view corresponding to a pixel unit of a display panel according to an embodiment;

FIG. 7 is a schematic cross-sectional view of a portion of a display device according to an embodiment;

FIG. 8 is a schematic cross-sectional view illustrating a portion of a display device according to an embodiment;

FIGS. 9A, 9B, 9C, 9D, and 9E are each a schematic cross-sectional view illustrating a portion of a method for manufacturing a display device according to an embodiment; and

FIG. 10 is a block diagram of an electronic device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, a display device and a method for manufacturing the display device according to an embodiment will be described with reference to the accompanying drawings.

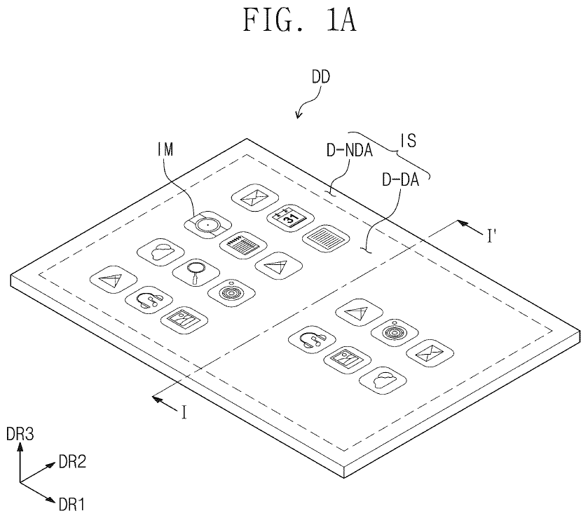

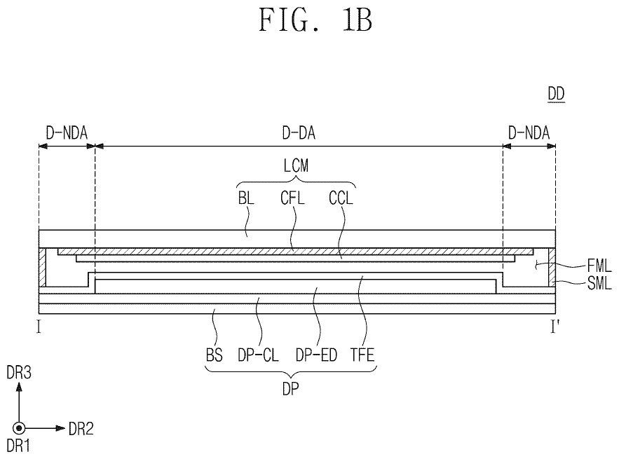

FIG. 1A is a schematic perspective view of a display device DD according to an embodiment. FIG. 1B is a schematic cross-sectional view of the display device DD according to an embodiment. FIG. 1B may be a schematic cross-sectional view taken along line I-I′ in FIG. 1A.

Referring to FIG. 1A, the display device DD may be a device that is activated in response to an electrical signal and displays an image IM. The display device DD may include various embodiments, and for example, the display device DD may include a large-sized device such as a television or an outdoor billboard, and also a small-and medium-sized device such as a monitor, a mobile phone, a tablet computer, a navigation device, a game console. However, embodiments of the display device DD are examples, and are not limited to any one unless departing from the invention.

FIG. 1A and the following drawings illustrate first, second, and third directions DR1, DR2 and DR3, and directions indicated by the first, second, and third directions DR1, DR2 and DR3 used herein are just provided as an example and are not limited thereto. In the disclosure, a front surface (or top surface) and a rear surface (or bottom surface) of each member which constitutes the display device DD may be defined on the basis of the third direction DR3.

The term “on a plane” or “in a plan view” used herein may be defined as being in a state when viewed in the third direction DR3. The term “on a cross-section” used herein may be defined as being in a state when viewed in the first direction DR1 or the second direction DR2.

The display device DD may display the image IM in the third direction DR3 through a display surface IS parallel to a plane defined by the first direction DR1 and the second direction DR2. The third direction DR3 may be substantially parallel to a normal direction to the display surface IS. The display surface IS on which the image IM is displayed may correspond to a front surface of the display device DD. The image IM may include not only a dynamic image but also a still image. FIG. 1A illustrates icon images as an example of the image IM.

As an example, FIG. 1A illustrates the display device DD having the display surface IS that is a flat display surface. However, the shape of the display surface IS of the display device DD is not limited thereto, and may be a curved shape or a three-dimensional shape.

The display device DD may be flexible. The term “flexible” indicates a characteristic of being capable of bending, and may include all from a fully folded structure to a structure capable of bending at the level of several nanometers. For example, the flexible display device DD may include a curved display device or a foldable display device. However, an embodiment is not limited thereto, and the display device DD may be rigid.

The display surface IS of the display device DD may include a display area D-DA, and a peripheral area D-NDA adjacent to the display area D-DA. The display area D-DA may be an area that is activated in response to an electrical signal. The image IM may be displayed on the display area D-DA. The image IM may be visible to a user through the display area D-DA. In embodiments illustrated in FIG. 1A and the like, the display area D-DA is illustrated as having a rectangular shape. However, this is illustrated as an example, and the display area D-DA may have various shapes.

The peripheral area D-NDA may surround the display area D-DA. However, an embodiment is not limited thereto, and the peripheral area D-NDA may be defined (or formed) to have various shapes. The peripheral area D-NDA may be an area in which a driving circuit or driving line for driving the display area D-DA, various signal lines which provide electrical signals, and pads are disposed. The peripheral area D-NDA may be a non-display portion which does not display the image IM. The peripheral area D-NDA may correspond to a portion that has a predetermined (or certain) color and blocks light. The peripheral area D-NDA may be adjacent to the display area D-DA. For example, the peripheral area D-NDA may be disposed outside at least one side of the display area D-DA, and the peripheral area D-NDA may surround the display area D-DA. However, this is an example. The peripheral area D-NDA may be adjacent to only one side of the display area D-DA or disposed on a side surface of the display device DD, not on the front surface thereof, and the peripheral area D-NDA is not limited thereto and may be omitted.

The display device DD according to an embodiment may detect an external input applied from the outside. The external input may include various types such as pressure, temperature, and light provided from the outside. The external input may include not only an input caused by touching the display device DD (e.g., touch by the user's hand or pen) but also an input (e.g., hovering) applied by being adjacent to the display device DD.

Referring to FIG. 1B, the display device DD may include a display panel DP and a light control member LCM. The display panel DP and the light control member LCM may face each other in the third direction DR3. The display device DD may further include a sealing member SML which couples the display panel DP and the light control member LCM to each other. The display device DD may further include a filling layer FML disposed between the display panel DP and the light control member LCM. In an embodiment, at least one of the sealing member SML or the filling layer FML may be omitted.

The display panel DP may include a base substrate BS, a circuit element layer DP-CL, a display element layer DP-ED, and an encapsulation layer TFE.

The display panel DP may include insulating layers, a semiconductor pattern, a conductive pattern, a signal line, and the like. In manufacture of the display panel DP, the insulating layers, the semiconductor pattern, and the conductive pattern may be formed on the base substrate BS by using methods such as coating and deposition. Thereafter, the insulating layers, the semiconductor layer, and the conductive layer may be selectively patterned using a photolithography method. The semiconductor pattern, the conductive pattern, and the signal line, and the like, which are included in the circuit element layer DP-CL, may be formed through those processes. The semiconductor pattern of the circuit element layer DP-CL may be arranged over pixels according to a specific rule.

The light control member LCM may include light control patterns capable of converting optical properties of source light provided by the display panel DP. The light control member LCM may selectively convert a wavelength or a color of the source light, or transmit the source light. The light control member LCM may control color purity or color gamut ratios of light emitted from the display device DD, and may prevent reflection of external light incident from the outside of the display device DD. For example, in an embodiment, the light control member LCM may include a quantum dot which converts a wavelength of the source light provided by the display panel DP.

The light control member LCM may include a base layer BL, a color filter layer CFL, and a light control layer CCL. In an embodiment, the light control member LCM may be formed (e.g., directly formed) on the display panel DP through a continuous process, and the base layer BL may be omitted in the light control member LCM. The color filter layer CFL and the light control layer CCL will be described later.

The sealing member SML may be disposed in the peripheral area D-NDA of the display device DD and prevent foreign matter, oxygen, moisture, and the like from being introduced (or permeated) into the display device DD from the outside. The sealing member SML may be made from a sealant including a curable resin.

The filling layer FML may fill a space between the display panel DP and the light control member LCM. The filling layer FML may function as a buffer between the display panel DP and the light control member LCM. In an embodiment, the filling layer FML may perform an impact absorbing function or the like, and may increase the strength of the display device DD. The filling layer FML may be made from a filling resin including a polymer resin. For example, the filling layer FML may be made from a filling layer resin including an acrylic resin, an epoxy-based resin, or the like. In an embodiment, the filling layer FML and the sealing member SML may be omitted, and a gap may be defined between the display panel DP and the light control member LCM.

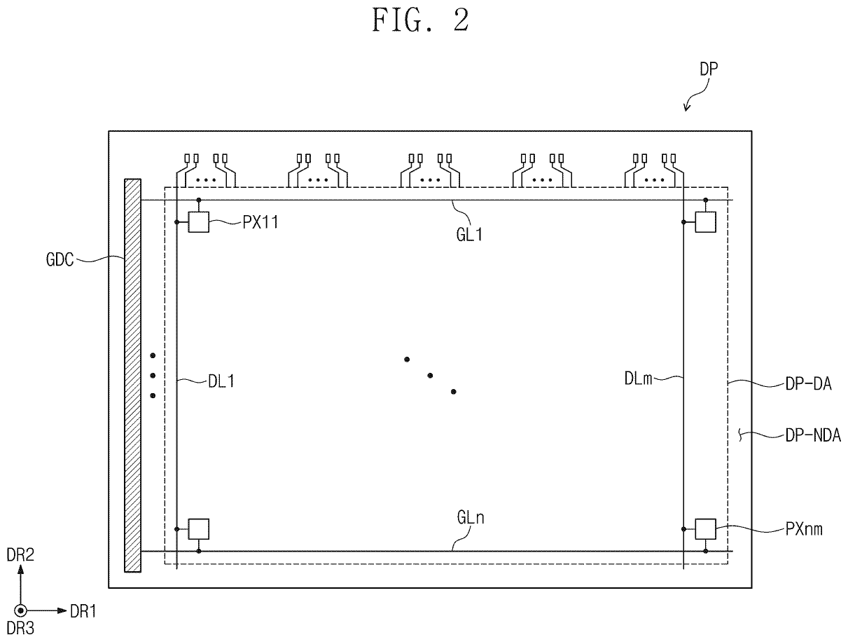

FIG. 2 is a schematic plan view of a display panel DP according to an embodiment.

Referring to FIG. 2, the display panel DP may include a display area DP-DA and a non-display area DP-NDA. The display area DP-DA may correspond to (or overlap) the display area D-DA of the display device DD (see FIG. 1B), and the non-display area DP-NDA may correspond to (or overlap) the peripheral area D-NDA of the display device DD. Pixels PX11 to PXnm may be disposed in the display area DP-DA, and the pixels PX11 to PXnm may not be disposed in the non-display area DP-NDA. The non-display area DP-NDA may surround the display area DP-DA. However, an embodiment is not limited thereto, and in an embodiment, the non-display area DP-NDA may be omitted or disposed at only one side of the display area DP-DA.

FIG. 2 illustrates a planar arrangement relationship of signal lines GL1 to GLn and DL1 to DLm and the pixels PX11 to PXnm.

The signal lines GL1 to GLn and DL1 to DLm may include gate lines GL1 to GLn and data lines DL1 to DLm. Each of the pixels PX11 to PXnm may be connected to a corresponding gate line of the gate lines GL1 to GLn and a corresponding data line of the data lines DL1 to DLm. Each of the pixels PX11 to PXnm may include a pixel driving circuit and a display element. According to the configuration of the pixel driving circuit of the pixels PX11 to PXnm, more types of signal lines may be provided in the display panel DP.

A gate driving circuit GDC may be integrated on the display panel DP through an oxide silicon gate driver circuit (OSG) or amorphous silicon gate driver circuit (ASG) process.

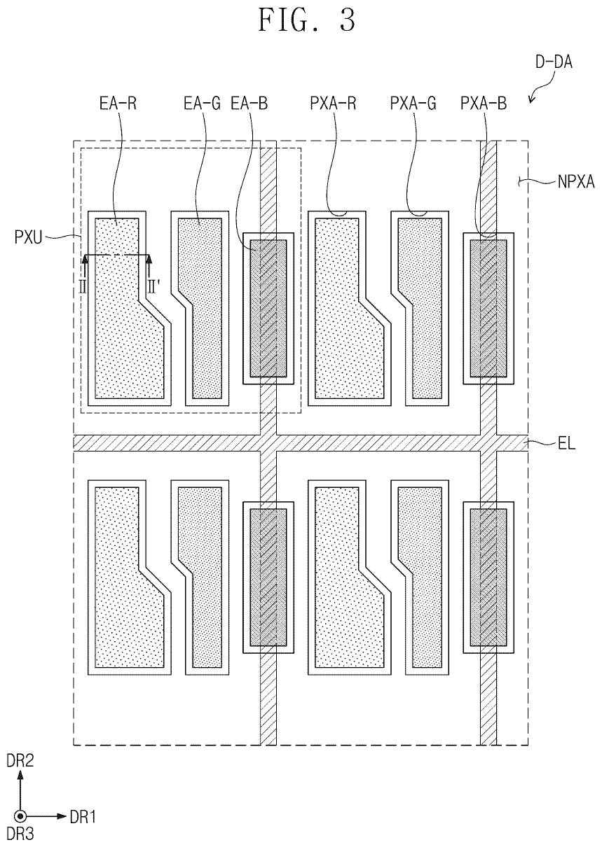

FIG. 3 is an enlarged schematic plan view of a portion of a display area D-DA of a display device DD according to an embodiment.

FIG. 3 illustrates an arrangement relationship of pixel areas PXA-R, PXA-G and PXA-B disposed in the display area D-DA (see FIG. 1A) in the display device DD (see FIG. 1A) according to an embodiment. The pixel areas PXA-R, PXA-G and PXA-B may be areas which correspond to (or overlap) the pixels PX11 to PXnm (see FIG. 2) in a one-to-one manner, and through which light generated from the pixels PX11 to PXnm (see FIG. 2) is provided to the outside. For example, the light generated from the pixels is light generated from light emitting elements of the pixels. For example, the pixel areas PXA-R, PXA-G and PXA-B may be defined in the light control member LCM illustrated in FIG. 1B. In an embodiment, three types of pixel areas PXA-R, PXA-G and PXA-B illustrated in FIG. 3 may be repeatedly disposed in the entirety of the display area DA.

In an embodiment, the display area D-DA of the display device DD may include a first pixel area PXA-R, a second pixel area PXA-G, and a third pixel area PXA-B which emit light in different wavelength regions. The first to third pixel areas PXA-R, PXA-G and PXA-B may be areas divided without overlapping each other in a plan view.

The first pixel area PXA-R may emit light having an emission wavelength of about 610 nm to about 700 nm, the second pixel area PXA-G may emit light having an emission wavelength of about 500 nm to about 590 nm, and the third pixel area PXA-B may emit light having an emission wavelength of about 410 nm to about 480 nm.

In an embodiment, the first pixel area PXA-R may be a red pixel area which emits red light, the second pixel area PXA-G may be a green pixel area which emits green light, and the third pixel area PXA-B may be a blue pixel area which emits blue light. However, an embodiment is not limited thereto, and in an embodiment, the display area D-DA may further include a pixel area which emits white light, in addition to the first to third pixel areas PXA-R, PXA-G and PXA-B.

In an embodiment, one first pixel area PXA-R, one second pixel area PXA-G, and one third pixel area PXA-B may be grouped to constitute a pixel unit (or single pixel unit) PXU. The arrangement of the pixel areas illustrated in FIG. 3 is an example, and unlike the illustrated embodiment, the pixel unit PXU may further include a pixel area which emits light in a different wavelength region, in addition to the first to third pixel areas PXA-R, PXA-G and PXA-B. In another example, the number of at least one of the first to third pixel areas PXA-R, PXA-G and PXA-B included in the pixel unit PXU may be two or more.

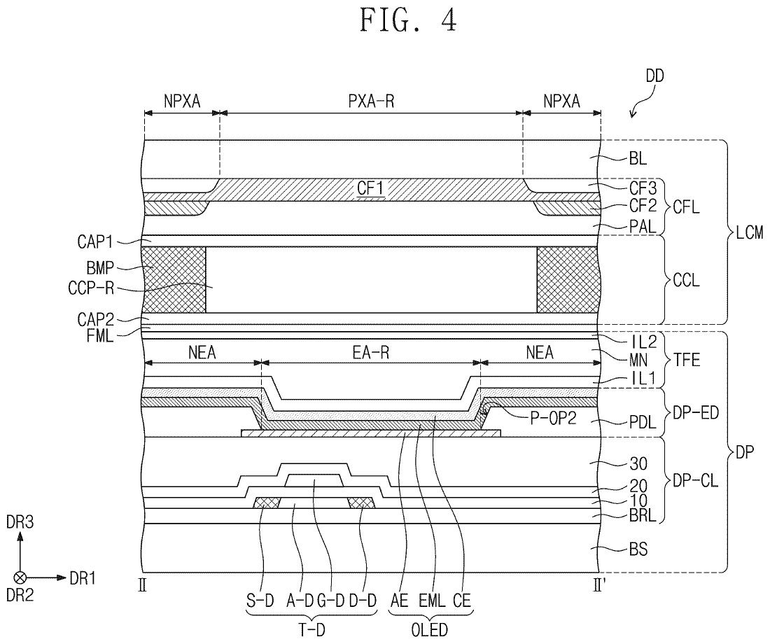

A non-pixel area NPXA may be disposed around the first to third pixel areas PXA-R, PXA-G and PXA-B. The non-pixel area NPXA may be disposed in a shape surrounding each of the first pixel area PXA-R, the second pixel area PXA-G, and the third pixel area PXA-B. The non-pixel area NPXA may set a boundary between the first to third pixel areas PXA-R, PXA-G and PXA-B, and prevent color mixture between the first to third pixel areas PXA-R, PXA-G and PXA-B. A structure which prevents the color mixture between the first to third pixel areas PXA-R, PXA-G and PXA-B, i.e., a stacked structure of first to third color filters CF1, CF2 and CF3 (see FIG. 4), may be disposed in the non-pixel area NPXA.

In an embodiment illustrated in FIG. 3, a portion of the first to third pixel areas PXA-R, PXA-G and PXA-B may have a rectangular shape. The remaining portion of the first to third pixel areas PXA-R, PXA-G and PXA-B may have a polygonal shape having a protrusion protruding from a rectangular shape. At least a portion of each of the first to third pixel areas PXA-R, PXA-G and PXA-B may have a polygonal shape having a short side extending in the first direction DR1 and a long side extending in the second direction DR2. Respective surface areas of the first to third pixel areas PXA-R, PXA-G and PXA-B may be set according to emissive colors. A surface area of a pixel area which emits light of a blue color that is one of primary colors may be the smallest, and a surface area of a pixel area which emits light of a red color that is one of the primary colors may be the largest. In another example, the surface area of the pixel area, which emits the light of the red color, and a surface area of a pixel area which emits light of a green color may be substantially the same.

FIG. 3 illustrates the first to third pixel areas PXA-R, PXA-G and PXA-B each having a rectangular shape or a polygonal shape, but an embodiment is not limited thereto. A portion of the first to third pixel areas PXA-R, PXA-G and PXA-B may have a polygonal shape (including a substantially polygonal shape) with a different shape in a plan view. In an embodiment, each of the first to third pixel areas PXA-R, PXA-G and PXA-B may have a rectangular shape with rounded corner areas (substantially rectangular shape) or a polygonal shape with rounded corner areas (substantially polygonal shape) in a plan view.

A first emission area EA-R, a second emission area EA-G, and a third emission area EA-B may correspond to (or overlap) the first pixel area PXA-R, the second pixel area PXA-G, and the third pixel area PXA-B, respectively. For example, the first to third emission areas EA-R, EA-G and EA-B may be defined in the display panel DP illustrated in FIG. 1B.

The first to third emission areas EA-R, EA-G and EA-B may overlap the first to third pixel areas PXA-R, PXA-G and PXA-B, respectively, and have smaller surface areas than corresponding pixel areas, respectively, in a plan view.

FIG. 3 additionally illustrates a power line EL disposed in the display area D-DA. For example, the power line EL may be disposed in the display panel DP illustrated in FIG. 1B.

The power line EL may receive a power voltage. FIG. 3 illustrates the power line EL having a line portion extending in a direction parallel to the first direction DR1, and a line portion extending in a direction parallel to the second direction DR2. However, an embodiment is not limited thereto. In an embodiment, the power line EL may have a lattice shape surrounding each of the first to third emission areas EA-R, EA-G and EA-B. As long as the power line EL may supply the power voltage to each of the pixels PX11 to PXnm (see FIG. 2), the power line EL may have various shapes without being limited to any one embodiment. The power line EL will be described later in detail.

FIG. 4 is a schematic cross-sectional view of a portion of a display device DD according to an embodiment. FIG. 4 illustrates a cross-section taken along line II-II′ illustrated in FIG. 3.

Referring to FIG. 4, a display panel DP and a light control member LCM may face each other in the third direction DR3. A filling layer FML may be disposed between the display panel DP and the light control member LCM.

Referring to FIG. 4, the display panel DP according to an embodiment may include a base substrate BS, a circuit element layer DP-CL disposed on the base substrate BS, a display element layer DP-ED disposed on the circuit element layer DP-CL, and an encapsulation layer TFE.

The base layer BL may be a member that provides a reference surface on which a component included in the circuit element layer DP-CL is disposed. In an embodiment, the base substrate BS may be a glass substrate, a metal substrate, a polymer substrate, or the like. However, an embodiment is not limited thereto, and the base substrate BS may be an inorganic layer, a functional layer, or a composite material layer.

The base substrate BS may have a multilayer structure. For example, the base substrate BS may have a three-layer structure including a polymer resin layer, an adhesive layer, and a polymer resin layer. For example, the polymer resin layer may include a polyimide-based resin. For example, the polymer resin layer may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, or a perylene-based resin. The term “α-based” resin used herein indicates one including a functional group of “α”.

The circuit element layer DP-CL may be disposed on the base substrate BS. The circuit element layer DP-CL may include a transistor T-D as a circuit element. As a driving circuit of a pixel is designed, the configuration of the circuit element layer DP-CL may be changed, and FIG. 4 illustrates one transistor T-D as an example. An arrangement relationship of an active A-D, a source S-D, a drain D-D, and a gate G-D which constitute the transistor T-D is illustrated as an example. The active A-D, the source S-D, and the drain D-D may be regions divided according to a doping concentration or conductivity of a semiconductor pattern.

The circuit element layer DP-CL may include a lower buffer layer BRL, a first insulating layer 10, a second insulating layer 20, and a third insulating layer 30 which are disposed on the base substrate BS. For example, the lower buffer layer BRL, the first insulating layer 10, and the second insulating layer 20 may be inorganic layers, and the third insulating layer 30 may be an organic layer.

The display element layer DP-ED may include a light emitting element OLED as a display element. The light emitting element OLED may generate source light. In an embodiment, the source light may be white light or blue light. The light emitting element OLED may include a first electrode AE, a second electrode CE, and an emission unit EML disposed between the first electrode AE and the second electrode CE. In this embodiment, the display element layer DP-ED may include an organic light emitting diode as the light emitting element OLED. In an embodiment, the light emitting element OLED may include a quantum-dot light emitting diode. For example, the emission unit EML included in the light emitting element OLED may include an organic light emitting material as a light emitting material, or the emission unit EML may include a quantum dot as a light emitting material. In another example, in this embodiment, the display element layer DP-ED may include an ultra-small light emitting element as the light emitting element OLED. The ultra-small light emitting element may include, for example, a micro LED element and/or a nano LED element, or the like. The ultra-small light emitting element may be a light emitting element having a micro-scale size or a nano-scale size and including an active layer disposed between multiple semiconductor layers.

The first electrode AE may be disposed on the third insulating layer 30. The first electrode AE may be directly or indirectly connected to the transistor T-D, and a connection structure of the first electrode AE and the transistor T-D is not illustrated in FIG. 4. At least a portion of the first electrode AE may be exposed by an emission opening portion P-OP2.

The display element layer DP-ED may include a pixel defining film PDL. For example, the pixel defining film PDL may be an organic layer. The emission opening portion P-OP2 may be defined in the pixel defining film PDL. The emission opening portion P-OP2 may expose at least a portion of the first electrode AE. The emission opening portion P-OP2 may correspond to (or overlap) a first emission area EA-R. The first emission area EA-R, the second emission area EA-G (see FIG. 3), and the third emission area EA-B (see FIG. 3) may be areas divided by the pixel defining film PDL.

For example, an emission opening portion may be defined in the pixel defining film PDL so as to correspond to (or to overlap) each of the second emission area EA-G and the third emission area EA-B in FIG. 3. A non-emission area NEA may be defined to be adjacent to the first emission area EA-R, and the non-emission area NEA may surround the first emission area EA-R in a plan view. The non-emission area NEA may be disposed between the first emission area EA-R, the second emission area EA-G, and the third emission area EA-B in FIG. 3.

The emission unit EML may be disposed on the first electrode AE. The emission unit EML may overlap the first emission area EA-R, the second emission area EA-G, the third emission area EA-B, and the non-emission area NEA. The second electrode CE may be disposed on the emission unit EML, and may overlap the first emission area EA-R and the non-emission area NEA. Although FIG. 4 illustrates the second electrode CE overlapping the first emission area EA-R, the second electrode CE may also overlap the second emission area EA-G (see FIG. 3) or the third emission area EA-B (see FIG. 3).

The encapsulation layer TFE may include an organic material or an inorganic material. The encapsulation layer TFE may have a multilayer structure in which an inorganic layer/an organic layer are repeated. In this embodiment, the encapsulation layer TFE may include a first encapsulation layer IL1, an organic encapsulation layer MN, and a second encapsulation layer IL2. The first and second encapsulation layers IL1 and IL2 may protect the light emitting element OLED from external moisture, and the organic encapsulation layer MN may prevent a dent defect of the light emitting element OLED from occurring due to foreign matter introduced (or permeated) during a manufacture process. For example, the display panel DP may further include, above the encapsulation layer TFE, a refractive index control layer for improving luminance efficiency.

As illustrated in FIG. 4, the light control member LCM may include a base layer BL, a color filter layer CFL disposed below the base layer BL, and a light control layer CCL disposed below the color filter layer CFL.

The base layer BL may be a member that provides a reference surface on which the color filter layer CFL, the light control layer CCL, and the like are disposed. The base layer BL may be a glass substrate, a metal substrate, a plastic substrate, or the like. However, an embodiment is not limited thereto, and the base layer BL may be an inorganic layer, an organic layer, or a composite material layer. In another example, unlike the illustrated embodiment, the base layer BL may be omitted in an embodiment.

The color filter layer CFL may be disposed below the base layer BL. The color filter layer CFL may include first to third color filters CF1, CF2 and CF3, and include a passivation PAL. The color filter layer CFL may include at least one color filter. The color filter may transmit light in a specific wavelength range, and block light in a wavelength range other than the specific wavelength range. The first color filter CF1 corresponding to a first pixel area PXA-R may transmit red light, and block green light and blue light.

The first color filter CF1 may include a base resin and a pigment and/or a dye dispersed in the base resin. The base resin is a medium in which a pigment and/or a dye are dispersed, and may include various resin compositions that are generally referred to as binders.

The first color filter CF1 may have a uniform thickness in the first pixel area PXA-R. Light, which is red light converted through a first light control pattern CCP-R from source light that is blue light, may be provided to the outside with uniform luminance in the first pixel area PXA-R.

The passivation PAL may fill a space between the light control layer CCL and the first to third color filters CF1, CF2, and CF3. The passivation PAL may be disposed (e.g., directly disposed) on a first barrier layer CAP1, and the first to third color filters CF1, CF2 and CF3 may be disposed (e.g., directly disposed) on the passivation PAL. A bottom surface (or lower surface) of the passivation PAL may be in contact with a top surface (or upper surface) of the first barrier layer CAP1, and a top surface (or upper surface) of the passivation PAL may be in contact with bottom surfaces (or lower surfaces) of the first to third color filters CF1, CF2 and CF3 of the color filter layer CFL.

The passivation PAL may function as a buffer between the light control layer CCL and the first to third color filters CF1, CF2 and CF3. In an embodiment, the passivation PAL may perform an impact absorbing function or the like, and may increase the strength of the display panel DP. The passivation PAL may be made from a filling resin including a polymer resin. For example, the passivation PAL may be made from a filling layer resin including an acrylic resin, an epoxy-based resin, or the like.

The passivation PAL may be disposed between the light control layer CCL and the first to third color filters CF1, CF2 and CF3 to function as an optical functional layer that increases light extraction efficiency or prevents incidence of reflected light on the light control layer CCL. The passivation PAL may be a layer having a lower refractive index than a layer adjacent thereto.

The light control layer CCL may be disposed below the color filter layer CFL. The light control layer CCL may include a bank BMP, the first light control pattern CCP-R, and a second barrier layer CAP2.

The bank BMP may include a base resin and an additive. The base resin may include various resin compositions that are generally referred to as binders. The additive may include a coupling agent and/or a photoinitiator. The additive may further include a dispersing agent.

The bank BMP may include a black component (e.g., black coloring agent) to block light. The bank BMP may include a black dye or a black pigment mixed in the base resin. In an embodiment, the black component may include a carbon black, a metal such as chrome, or an oxide thereof.

The first light control pattern CCP-R may be disposed inside the bank BMP. The first light control pattern CCP-R may change optical properties of the source light.

The first light control pattern CCP-R may include a quantum dot for changing the optical properties of the source light. The first light control pattern CCP-R may include a first quantum dot which converts the source light to light having a different wavelength. In the first light control pattern CCP-R overlapping the first pixel area PXA-R, the first quantum dot may convert the source light into red light.

In the disclosure, the quantum dot may indicate a crystal of a semiconductor compound. The quantum dot may emit light having various emission wavelengths according to the size of the crystal. The quantum dot may emit light having various emission wavelengths by adjusting a ratio of elements in a quantum dot compound.

A diameter of the quantum dot may be in a range of about 1 nm to about 10 nm.

The quantum dot may be synthesized through a wet chemical process, an organic metal chemical vapor deposition process, a molecular beam epitaxy process, or a similar process.

The wet chemical process may be a method of mixing an organic solvent and a precursor material and then growing quantum dot particle crystals. In case that the crystals grow, the organic solvent may naturally serve as a dispersant coordinated on surfaces of the quantum dot crystals, and may control the growth of the crystals. Thus, in the wet chemical process, the growth of quantum dot particles may be controlled through a process performed more easily and at lower costs than a vapor deposition process such as metal organic chemical vapor deposition (MOCVD) or molecular beam epitaxy (MBE).

A core of the quantum dot may be selected from a Group II-VI compound, a Group III-V compound, a Group III-VI compound, a Group I-III-VI compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof. For example, a Group II-VI semiconductor compound may further include a Group I metal and/or a Group IV element. The Group I-II-VI compound may be selected from CuSnS or CuZnS, the Group II-IV-VI compound may be selected from ZnSnS or the like. The Group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and a mixture thereof.

The Group III-VI compound may include a binary compound such as In₂S₃ and In₂Se₃, a ternary compound such as InGaS₃ and InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound such as AgInGaS₂ or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. For example, the Group III-V compound may further include a Group II metal. For example, InZnP or the like may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

Examples of the Group II-IV-V semiconductor compound may include a ternary compound selected from the group consisting of ZnSnP, ZnSnP₂, ZnSnAs₂, ZnGeP₂, ZnGeAs₂, CdSnP₂, CdGeP₂, and a mixture thereof.

The Group IV element may be selected from the group consisting of Si, Ge, and a mixture thereof. The Group IV compound may be a binary compound selected from the group consisting of SiC, SiGe, and a mixture thereof.

Each of elements included in a multi-element compound such as the binary compound, the ternary compound and the quaternary compound, may be present in a particle at a uniform concentration or non-uniform concentration. For example, the foregoing formulas indicate types of the elements included in the compound, and ratios of elements in the compound may be different. For example, AgInGaS₂ may indicate AgInₓGa₁₋ₓS₂ (here, x may be a real number between 0 and 1).

For example, the binary compound, the ternary compound, or the quaternary compound may be present at a uniform concentration in a particle, or may be present in the same particle while having partially different concentration distributions. For example, the quantum dot may have a core/shell structure in which one quantum dot surrounds another quantum dot. In the core/shell structure, the quantum dot may have a concentration gradient in which the concentration of an element present in the shell gradually decreases toward the core.

In some embodiments, the quantum dot may have a core-shell structure including a core having the aforementioned nanocrystal and a shell surrounding the core. The shell of the quantum dot may serve as a protective layer for preventing chemical modification of the core to maintain semiconductor characteristics, and/or serve as a charging layer for imparting electrophoretic characteristics to the quantum dot. The shell may be a single-layer shell or a multilayer shell. Examples of the shell of the quantum dot may include a metal or nonmetal oxide, a semiconductor compound, a combination thereof, or the like.

For example, the metal or nonmetal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but an embodiment is not limited thereto.

For example, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but an embodiment is not limited thereto.

The quantum dot may have a full width of half maximum (FWHM) of an emission wavelength spectrum of about 45 nm or less, e.g., about 40 nm or less, e.g., about 30 nm or less. In this range, color purity or color reproducibility may be improved. Moreover, light emitted through such quantum dots may be emitted in all directions, and thus a wide viewing angle may be improved.

For example, the form of the quantum dot may be a form generally used in the relevant field, but embodiments are not limited thereto. For example, spherical, pyramidal, multi-armed, or cubic nanoparticles, or nanoparticles in the form of nanotubes, nanowires, nanofibers, or nanoplate, or the like, may be used.

In the quantum dot, an energy band gap may be adjusted by adjusting the size of the quantum dot or adjusting the ratio of elements in a quantum dot compound, and thus light in various wavelength bands may be obtained in the quantum dot emission layer. Thus, the quantum dots (having different sizes or having different ratios of elements in a quantum dot compound) as described above may be used to achieve a light emitting element that emits light having several wavelengths. For example, the size of the quantum dot or the ratio of elements in the quantum dot compound may be selectively adjusted so as to emit red, green and/or blue light. Also, the quantum dots may emit white light by combining light of various colors.

In an embodiment, a quantum dot included in the first light control pattern CCP-R corresponding to the first pixel area PXA-R may have a red emissive color. As the particle size of the quantum dot is decreased, the quantum dot may emit light in a shorter-wavelength range. For example, in quantum dots having the same core, a particle size of the quantum dot which emits green light may be less than a particle size of the quantum dot which emits red light. For example, in the quantum dots having the same core, a particle size of the quantum dot which emits blue light may be less than the particle size of the quantum dot which emits the green light. However, an embodiment is not limited thereto, and, even in the quantum dots having the same core, the particle sizes thereof may be adjusted according to a material constituting the shell, a shell thickness, and the like.

For example, in a case in which quantum dots have various emissive colors such as blue, red, and green, the quantum dots having different emissive colors may be different from each other in terms of the core materials.

The first light control pattern CCP-R may further include a scatterer. The first light control pattern CCP-R may include the first quantum dot which converts the blue light to the red light, and the scatterer which scatters light.

The scatterer may be an inorganic particle. For example, the scatterer may include at least one of TiO₂, ZnO, Al₂O₃, SiO₂, or hollow silica. The scatterer may include any one of TiO₂, ZnO, Al₂O₃, SiO₂, and hollow silica, or may be a mixture of two or more materials selected from TiO₂, ZnO, Al₂O₃, SiO₂, and hollow silica.

The first light control pattern CCP-R may include a base resin which disperses the first quantum dot and the scatterer. The base resin may be a medium in which the first quantum dot and the scatterer are dispersed, and may include various resin compositions that are generally referred to as binders. For example, the base resin may be an acrylic resin, a urethane-based resin, a silicone resin, an epoxy-based resin, or the like. The base resin may be a transparent resin.

In this embodiment, the first light control pattern CCP-R may be formed through an inkjet process. The composition which is polymerized by a thermal curing process or a photocuring process may be reduced in volume after the curing.

The light control layer CCL may include the first barrier layer CAP1 disposed on a surface (or single side) of the first light control pattern CCP-R. The first barrier layer CAP1 may serve to prevent permeation of moisture and/or oxygen (hereinafter referred to as “moisture/oxygen”) and adjust a refractive index to improve optical characteristics. The first barrier layer CAP1 may be disposed on a surface (or single side) of an upper side of the first light control pattern CCP-R, thereby preventing the first light control pattern CCP-R from being exposed to moisture/oxygen, e.g., preventing the quantum dot included in the first light control pattern CCP-R from being exposed to moisture/oxygen. The first barrier layer CAP1 may also protect the first light control pattern CCP-R from an external impact. In an embodiment, the first barrier layer CAP1 may be disposed to be spaced apart from the display element layer DP-ED with the first light control pattern CCP-R disposed on the display element layer DP-ED. For example, the first barrier layer CAP1 may be disposed on a top surface (or upper surface) of the first light control pattern CCP-R. The first barrier layer CAP1 may cover a surface (or single surface) of each of the bank BMP and the first light control pattern CCP-R.

In an embodiment, the light control layer CCL may include the second barrier layer CAP2 disposed between the first light control pattern CCP-R and the display element layer DP-ED. The first barrier layer CAP1 may cover the top surface (or upper surface) of the first light control pattern CCP-R, and the second barrier layer CAP2 may cover the bottom surface (or lower surface) of the first light control pattern CCP-R adjacent to the display element layer DP-ED. For example, in the disclosure, a top surface (or upper surface) may be a surface placed on an upper side on the basis of the third direction DR3, and a bottom surface (or lower surface) may be a surface placed on a lower side on the basis of the third direction DR3.

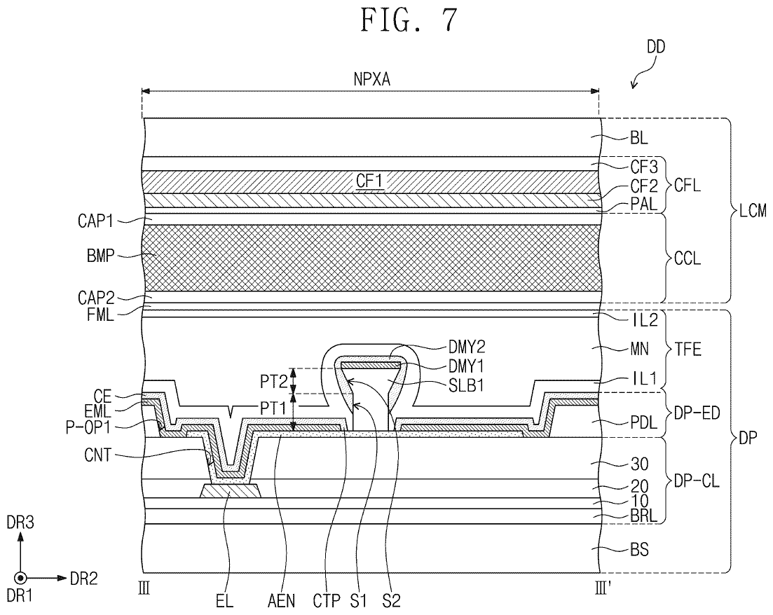

The second barrier layer CAP2 may be disposed (e.g., directly disposed) on the encapsulation layer TFE. The light control layer CCL may be disposed on the display element layer DP-ED, the encapsulation layer TFE, and the filling layer FML disposed on the encapsulation layer TFE. Light control patterns CCP-R, CCP-G and CCP-B (see FIG. 7) of the light control layer CCL may be formed, through a continuous process, on the second barrier layer CAP2 disposed on the encapsulation layer TFE.

For example, each of the first barrier layer CAP1 and the second barrier layer CAP2 may cover not only the surface of the first light control pattern CCP-R, but also a surface of the bank BMP. The first barrier layer CAP1 and the second barrier layer CAP2 may each include an inorganic material. In the display panel DP according to an embodiment, the first barrier layer CAP1 may include a silicon oxynitride (SiOₓN_{y}). Both the first barrier layer CAP1 and the second barrier layer CAP2 may include silicon oxynitrides (SiOₓN_{y}). However, an embodiment is not limited thereto, and each the first barrier layer CAP1 and the second barrier layer CAP2 may include a silicon oxide (SiOₓ) or a silicon nitride (SiNₓ). In an embodiment, the first barrier layer CAP1 disposed on the first light control pattern CCP-R may include a silicon oxynitride (SiOₓN_{y}), and the second barrier layer CAP2 disposed below the first light control pattern CCP-R may include a silicon oxide (SiOₓ).

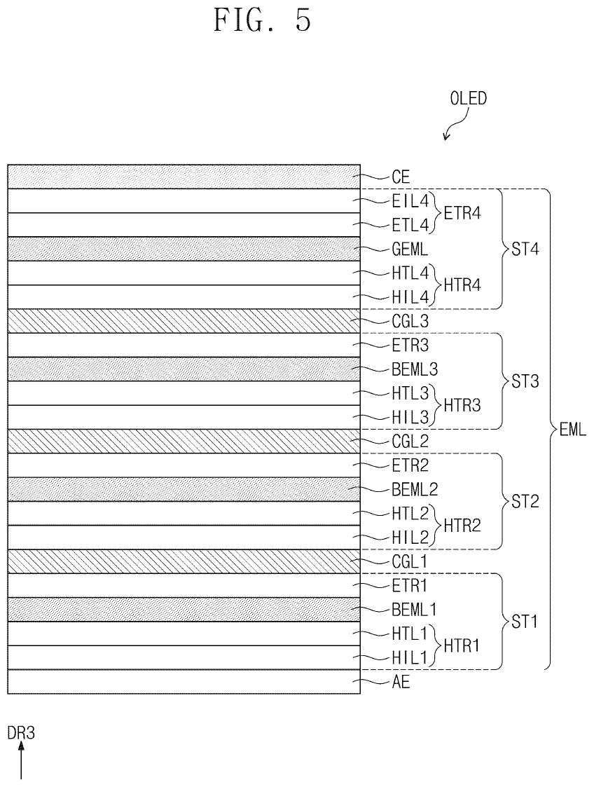

FIG. 5 is a schematic cross-sectional view of a light emitting element OLED according to an embodiment. FIG. 5 is an enlarged schematic view illustrating the light emitting element OLED in FIG. 4.

Referring to FIG. 5, the light emitting element OLED according to an embodiment may include a first electrode AE, a second electrode CE facing the first electrode AE, and an emission unit EML disposed between the first electrode AE and the second electrode CE. The emission unit EML may include a first emission structure ST1, a second emission structure ST2, a third emission structure ST3, and a fourth emission structure ST4, which include emission layers BEML1, BEML2, BEML3 and GEML, respectively, and are stacked in a thickness direction. As an example, FIG. 5 illustrates an embodiment in which the light emitting element OLED includes the four emission structures, but the number of the emission structures included in the light emitting element OLED may be less than four, or more than four.

The light emitting element OLED may include first to third charge generation layers CGL1, CGL2 and CGL3, each of which is disposed in a space between emission structures adjacent to each other among the first to fourth emission structures ST1, ST2, ST3 and ST4.

In case that a voltage is applied, each of the first to third charge generation layers CGL1, CGL2 and CGL3 may generate charges (e.g., electrons and holes) by forming a complex through an oxidation-reduction reaction. Thereafter, the first to third charge generation layers CGL1, CGL2 and CGL3 may provide the generated charges to the first to fourth emission structures ST1, ST2, ST3 and ST4. The first to third charge generation layers CGL1, CGL2 and CGL3 may double (or increase) efficiency of current generated from the first to fourth emission structures ST1, ST2, ST3 and ST4, and may serve to adjust the balance of the charges between the first to fourth emission structures ST1, ST2, ST3 and ST4.

Each of the first to third charge generation layers CGL1, CGL2 and CGL3 may include an n-type layer and a p-type layer. The first to third charge generation layers CGL1, CGL2 and CGL3 may have a structure in which the n-type layer and the p-type layer are bonded to each other. However, an embodiment is not limited thereto, and the first to third charge generation layers CGL1, CGL2 and CGL3 may include only one of the n-type layer and the p-type layer. The n-type layer may be a charge generation layer that provides electrons to an adjacent emission structure. The n-type layer may be a layer in which a base material is doped with an n-dopant. The p-type layer may be a charge generation layer that provides holes to an adjacent emission structure.

In an embodiment, each of the first to third charge generation layers CGL1, CGL2 and CGL3 may have a thickness of about 1 angstrom (Å) to about 150 angstroms (Å). The n-dopant doped in the first to third charge generation layers CGL1, CGL2 and CGL3 may have a concentration of about 0.1% to about 3%, and, e.g., about 1% or less. In case that the concentration is less than about 0.1 %, effects of the first to third charge generation layers CGL1, CGL2 and CGL3 which adjust the balance of the charges may hardly occur. In case that the concentration is more than about 3%, the luminance efficiency of the light emitting element OLED may be decreased.

Each of the first to third charge generation layers CGL1, CGL2 and CGL3 may include a charge generation compound including an aryl amine-based organic compound, a metal, an oxide, carbide, or fluoride of metal, or a mixture thereof. For example, the aryl amine-based organic compound may include α-NPD, 2-TNATA, TDATA, MTDATA, sprio-TAD, or sprio-NPB. The metal may include cesium (Cs), molybdenum (Mo), vanadium (V), titanium (Ti), tungsten (W), barium (Ba), or lithium (Li). The oxide, carbide, and fluoride of metal may include Re₂O₇, MoO₃, V₂O₅, WO₃, TiO₂, Cs₂CO₃, BaF, LiF, or CsF. However, the materials of the first to third charge generation layers CGL1, CGL2 and CGL3 are not limited to the foregoing examples.

Each of the first to fourth emission structures ST1, ST2, ST3 and ST4 may include the emission layer. The first emission structure ST1 may include a first emission layer BEML1, the second emission structure ST2 may include a second emission layer BEML2, the third emission structure ST3 may include a third emission layer BEML3, and the fourth emission structure ST4 may include a fourth emission layer GEML. Some of the emission layers included in the first to fourth emission structures ST1, ST2, ST3 and ST4 may emit light of substantially the same color, and some thereof may emit light of different colors.

In an embodiment, the first to third emission layers BEML1, BEML2 and BEML3 of the first to third emission structures ST1, ST2 and ST3 may emit light of substantially the same first color. For example, the light of the first color may be blue light that is the aforementioned source light. The light emitted by the first to third emission structures ST1, ST2 and ST3 may have a wavelength range of about 420 nm to about 480 nm.

The fourth emission layer GEML of the fourth emission structure ST4 may emit light of a second color different from the light of the first color. For example, the light of the second color may be green light. The light emitted by the fourth emission layer GEML may have a wavelength range of about 520 nm to about 600 nm.

The light emitting element OLED may emit light in a direction from the first electrode AE to the second electrode CE. In the light emitting element OLED according to an embodiment, the first to fourth emission structures ST1, ST2, ST3 and ST4 may include hole transport regions HTR1, HTR2, HTR3 and HTR4 and electron transport regions ETR1, ETR2, ETR3 and ETR4, respectively. The hole transport regions HTR1, HTR2, HTR3 and HTR4 may transport holes provided from the first electrode AE or the charge generation layers CGL1, CGL2 and CGL3 to the emission layers. The electron transport regions ETR1, ETR2, ETR3 and ETR4 may transport electrons provided from the second electrode CE or the charge generation layers CGL1, CGL2 and CGL3 to the emission layers.

As an example, the light emitting element OLED according to an embodiment is illustrated as having a structure in which, based on a direction in which the light is emitted, the hole transport regions HTR1, HTR2, HTR3 and HTR4 are disposed below the emission layers BEML1, BEML2, BEML3 and GEML included in the first to fourth emission structures ST1, ST2, ST3 and ST4, respectively, and the electron transport regions ETR1, ETR2, ETR3 and ETR4 are disposed above the emission layers BEML1, BEML2, BEML3 and GEML included in the first to fourth emission structures ST1, ST2, ST3 and ST4, respectively. For example, the light emitting element OLED according to an embodiment may have a forward device structure. However, an embodiment is not limited thereto, and the light emitting element OLED may have an inverted device structure in which, based on the direction in which the light is emitted, the hole transport regions HTR1, HTR2, HTR3 and HTR4 are disposed below the emission layers BEML1, BEML2, BEML3 and GEML included in the first to fourth emission structures ST1, ST2, ST3 and ST4, respectively, and the electron transport regions ETR1, ETR2, ETR3 and ETR4 are disposed above the emission layers BEML1, BEML2, BEML3 and GEML included in the first to fourth emission structures ST1, ST2, ST3 and ST4, respectively.

The hole transport regions HTR1, HTR2, HTR3 and HTR4 may include hole injection layers HIL1, HIL2, HIL3 and HIL4, and hole transport layers HTL1, HTL2, HTL3 and HTL4 disposed on the hole injection layers HIL1, HIL2, HIL3 and HIL4, respectively. Each of the hole transport layers HTL1, HTL2, HTL3 and HTL4 may be in contact with a bottom surface (or lower surface) of the emission layer. However, an embodiment is not limited thereto, and the hole transport regions HTR1, HTR2, HTR3 and HTR4 may further include hole-side additional layers disposed on the hole transport layers HTL1, HTL2, HTL3 and HTL4, respectively. The hole-side additional layer may include at least one of a hole buffer layer, an emission auxiliary layer, or an electron blocking layer. The hole buffer layer may be a layer that compensates a resonance distance according to wavelengths of light emitted from the emission layer and increases light-emission efficiency. The electron blocking layer may be a layer that prevents electrons from being injected from an electron transport region to a hole transport region.

The electron transport regions ETR1, ETR2, ETR3 and ETR4 may include an electron transport layer. The electron transport regions ETR1, ETR2, ETR3 and ETR4 may further include an electron injection layer disposed on the electron transport layer. The electron transport regions ETR1, ETR2, ETR3 and ETR4 may further include an electron injection layer disposed on the electron transport layer. For example, a fourth electron transport region ETR4 included in the fourth emission structure ST4 may further include a fourth electron injection layer EIL4 disposed on a fourth electron transport layer ETL4. The electron transport regions ETR1, ETR2, ETR3 and ETR4 may further include an electron-side additional layer disposed between the electron transport layer and the emission layers. The electron-side additional layer may include at least one of an electron buffer layer or a hole blocking layer.

In the light emitting element OLED according to an embodiment, the first electrode AE may be a reflective electrode. For example, the first electrode AE may include Ag, Mg, Cu, Al, Pt, Pd, Au, Ni, Nd, Ir, Cr, Li, Ca, LiF/Ca, LiF/Al, Mo, Ti, W, In, Zn, or Sn, which has a high reflectance, or a compound or mixture thereof (e.g., a mixture of Ag and Mg). In another example, the first electrode AE may have a multilayer structure including a reflective film including the foregoing material, and a transparent conductive film including an indium tin oxide (ITO), an indium zinc oxide (IZO), a zinc oxide (ZnO), an indium tin zinc oxide (ITZO), or the like. For example, the first electrode AE may have a two-layer structure of ITO/Ag and a three-layer structure of ITO/Ag/ITO, but embodiments are not limited thereto. For example, the first electrode AE may include the foregoing metal material, a combination of two or more metal materials selected from the foregoing metal materials, an oxide of the foregoing metal materials, or the like. The first electrode AE may have a thickness of about 70 nm to about 1000 nm. For example, the thickness of the first electrode AE may be about 100 nm to about 300 nm.

In the light emitting element OLED according to an embodiment, each of the hole transport regions HTR1, HTR2, HTR3 and HTR4 may have a single layer made of a single material, or a single layer made of different materials, or a multilayer structure having multiple layers made of different materials.

Each of the hole transport regions HTR1, HTR2, HTR3 and HTR4 may be formed using various methods such as a vacuum deposition method, a spin coating method, a cast method, a Langmuir-Blodgett (LB) method, an inkjet printing method, a laser printing method, or a laser induced thermal imaging (LITI) method.

The hole transport regions HTR1, HTR2, HTR3 and HTR4 may each include a phthalocyanine compound such as copper phthalocyanine, N1,N1′-([1,1′-biphenyl]-4,4′-diyl)bis(N1-phenyl-N4,N4-di-m-tolylbenzene-1,4-diamine) (DNTPD), 4,4′,4″-[tris(3-methylphenyl)phenylamino] triphenylamine (m-MTDATA), 4,4′4″-Tris(N,N-diphenylamino)triphenylamine (TDATA), 4,4′,4″-tris[N(2-naphthyl)-N-phenylamino]-triphenylamine (2-TNATA), Poly(3,4-ethylenedioxythiophene)/Poly(4-styrenesulfonate) (PEDOT/PSS), Polyaniline/Dodecylbenzenesulfonic acid (PANI/DBSA), Polyaniline/Camphor sulfonicacid (PANI/CSA), Polyaniline/Poly(4-styrenesulfonate) (PANI/PSS), N,N′-di(naphthalene-1-yl)-N,N′-diphenyl-benzidine (NPB), triphenylamine-containing polyetherketone (TPAPEK), 4-Isopropyl-4′-methyldiphenyliodonium [Tetrakis(pentafluorophenyl)borate], dipyrazino[2,3-f: 2′, 3′-h] quinoxaline-2,3,6,7,10,11-hexacarbonitrile (HATCN), or the like.

The hole transport regions HTR1, HTR2, HTR3 and HTR4 may each include a carbazole derivative such as N-phenyl carbazole or polyvinyl carbazole, a fluorene-based derivative, a triphenylamine-based derivative such as N,N′-bis(3-methylphenyl)-N,N′-diphenyl-[1,1′-biphenyl]-4,4′-diamine (TPD) or 4,4′,4″-tris(N-carbazolyl)triphenylamine (TCTA), N,N′-di(naphthalene-l-yl)-N,N′-diphenyl-benzidine (NPB), 4,4′-Cyclohexylidene bis[N,N-bis(4-methylphenyl)benzenamine] (TAPC), 4,4′-Bis[N,N′-(3-tolyl)amino]-3,3′-dimethylbiphenyl (HMTPD), 1,3-Bis(N-carbazolyl)benzene (mCP), or the like.

In another example, the hole transport regions HTR1, HTR2, HTR3 and HTR4 may each include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), or the like.

In the hole transport regions HTR1, HTR2, HTR3 and HTR4, the foregoing compounds of the hole transport region may be included in at least one of the hole injection layers HIL1, HIL2, HIL3 and HIL4, the hole transport layers HTL1, HTL2, HTL3 and HTL4, or the hole-side additional layers.

Each of the hole transport regions HTR1, HTR2, HTR3 and HTR4 may have a thickness of about 10 nm to about 1000 nm, for example, a thickness of about 10 nm to about 500 nm. Each of the hole injection layers HIL1, HIL2, HIL3 and HIL4 may have a thickness of, for example, a thickness of about 5 nm to about 100 nm. Each of the hole transport layers HTL1, HTL2 HTL3 and HTL4 may have a thickness of about 5 nm to about 100 nm. In a case in which the hole transport regions HTR1, HTR2, HTR3 and HTR4 include the hole-side additional layer, the hole-side additional layer may have a thickness of about 1 nm to about 100 nm. In case that the thickness of each of the hole transport regions HTR1, HTR2, HTR3 and HTR4 and the layers included therein satisfies the foregoing range, satisfactory hole transport properties may be obtained without a substantial increase in driving voltage.

Each of the hole transport regions HTR1, HTR2, HTR3 and HTR4 may further include, in addition to the foregoing materials, a charge generation material to improve conductivity. The charge generation material may be uniformly or non-uniformly dispersed in the hole transport regions HTR1, HTR2, HTR3 and HTR4. The charge generation material may be, for example, a p-type dopant. The p-type dopant may include at least one of halogenated metal compounds, quinone derivatives, metal oxides, or cyano group-containing compounds, but embodiments are not limited thereto. For example, the p-type dopant may include halogenated metal compounds such as CuI and RbI, quinone derivatives such as Tetracyanoquinodimethane (TCNQ) and 2,3,5,6-tetrafluoro-7,7′8,8-tetracyanoquinodimethane (F4-TCNQ), metal oxides such as tungsten oxides and molybdenum oxides, or the like, but an embodiment is not limited thereto.

Each of blue emission layers BEML1, BEML2 and BEML3 and the fourth emission layer GEML may include a host material and a dopant material. Each of the blue emission layers BEML1, BEML2 and BEML3 and the fourth emission layer GEML may include, as a hole transporting host material, a material including a carbazole derivative moiety or an amine derivative moiety. Each of the blue emission layers BEML1, BEML2 and BEML3 and the fourth emission layer GEML may include, as an electron transporting host material, a material including a nitrogen-containing aromatic ring structure, such as a pyridine derivative moiety, a pyridazine derivative moiety, a pyrimidine derivative moiety, a pyrazine derivative moiety, or a triazine derivative moiety.

Each of the blue emission layers BEML1, BEML2 and BEML3 and the fourth emission layer GEML may include, as a host material, an anthracene derivative, a pyrene derivative, a fluoranthene derivative, a chrysene derivative, a dihydrobenzanthracene derivative, a triphenylene derivative, or the like. Each of the blue emission layers BEML1, BEML2 and BEML3 and the fourth emission layer GEML may further include, as a host material, a material generally used in this technical field. For example, each of the blue emission layers BEML1, BEML2 and BEML3 and the fourth emission layer GEML may include, as a host material, at least one of Bis[2-(diphenylphosphino)phenyl] ether oxide (DPEPO), 4,4′-Bis(carbazol-9-yl)biphenyl (CBP), 1,3-Bis(carbazol-9-yl)benzene (mCP), (2,8-Bis(diphenylphosphoryl)dibenzo[b, d]furan (PPF), 4,4′,4″-Tris(carbazol-9-yl)-triphenylamine (TCTA), or 1,3,5-tris(1-phenyl-1H-benzo[d]imidazole-2-yl)benzene (TPBi). However, an embodiment is not limited thereto, and, for example, tris(8-hydroxyquinolino)aluminum (Alq₃), poly(N-vinylcarbazole (PVK), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-Methyl-9,10-bis(naphthalen-2-yl)anthracene (MADN), Hexaphenyl cyclotriphosphazene (CP1), 1,4-Bis(triphenylsilyl)benzene (UGH2), Hexaphenylcyclotrisiloxane (DPSiO₃), Octaphenylcyclotetra siloxane (DPSiO₄), or the like, may be used as a host material.

In an embodiment, each of the blue emission layers BEML1, BEML2 and BEML3 may include, as a generally used dopant material, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi)), and 4,4′-bis[2-(4-(N, N-diphenylamino)phenyl)vinyl]biphenyl (DPAVBi), perylene and a derivative thereof (e.g., 2, 5, 8, 11-Tetra-t-butylperylene (TBP)), pyrene and a derivative thereof (e.g., 1,1-dipyrene, 1,4-dipyrenylbenzene, and 1,4-Bis (N, N-Diphenylamino)pyrene), or the like.

The fourth emission layer GEML may include a generally used phosphorescent dopant material. For example, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N, C2′)picolinate (FIrpic), Bis(2,4-difluorophenylpyridinato)-tetrakis(1-pyrazolyl)borate iridium(III) (Fir6), or platinum octaethyl porphyrin (PtOEP) may be used as a phosphorescent dopant material.

Each of the electron transport regions ETR1, ETR2, ETR3 and ETR4 may have a single layer made of a single material, or a single layer made of different materials, or a multilayer structure having multiple layers made of different materials. For example, at least a portion of the electron transport regions ETR1, ETR2, ETR3 and ETR4 may include the electron transport layer ETL4 and the electron injection layer EIL4.

Each of electron transport regions ETR1, ETR2, ETR3 and ETR4 may be formed using various methods such as a vacuum deposition method, a spin coating method, a cast method, a Langmuir-Blodgett (LB) method, an inkjet printing method, a laser printing method, or a laser induced thermal imaging (LITI) method.

The electron transport regions ETR1, ETR2, ETR3 and ETR4 may include anthracene-based compounds. However, an embodiment is not limited thereto, and each of the electron transport regions ETR1, ETR2, ETR3 and ETR4 may include, for example, Tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine (T2T), 2-(4-(N-phenylbenzoimidazol-1-yl)phenyl)-9,10-dinaphthylanthracene, 1,3,5-Tri(1-phenyl-1H-benzo[d]imidazol-2-yl)benzene (TPBi), 2,9-Dimethyl-4,7-diphenyl-1,10-phenanthroline (BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), Bis(2-methyl-8-quinolinolato-N1,O8)-(1,1′-Biphenyl-4-olato)aluminum (BAlq), berylliumbis(benzoquinolin-10-olate) (Bebq2), 9,10-di(naphthalene-2-yl)anthracene (ADN), 1,3-Bis[3,5-di(pyridin-3-yl)phenyl]benzene (BmPyPhB), and a mixture thereof.

Each of the electron transport regions ETR1, ETR2, ETR3 and ETR4 may include a halogenated metal such as LiF, NaCl, CsF, RbCl, RbI, CuI, or KI, a lanthanum group metal such as Yb, or a co-deposition material of the above halogenated metal and the lanthanum group metal. For example, the electron transport regions ETR1, ETR2, ETR3 and ETR4 may include KI:Yb, RbI:Yb, or the like as a co-deposition material. The electron transport regions ETR1, ETR2, ETR3 and ETR4 may include two or more materials selected from Mg, Ag, Yb, and Al. For example, the electron transport regions ETR1, ETR2, ETR3 and ETR4 may include Mg and Yb.

A metal oxide such as Li₂O or BaO, 8-hydroxyl-Lithium quinolate (Liq), or the like may be used for the electron transport regions ETR1, ETR2, ETR3 and ETR4, but an embodiment is not limited thereto. Each of the electron transport regions ETR1, ETR2, ETR3 and ETR4 may also include a material in which an electron transport material and an insulating organo-metal salt are mixed. The organo-metal salt may be a material having an energy band gap of about 4 eV or more. For example, the organo-metal salt may include metal acetate, metal benzoate, metal acetoacetate, metal acetylacetonate, or metal stearate.

Each of the electron transport regions ETR1, ETR2, ETR3 and ETR4 may further include, in addition to the foregoing materials, at least one of 2,9-dimethyl-4,7-diphenyl-1,10-phenanthroline (BCP) or 4,7-diphenyl-1,10-phenanthroline (Bphen), but an embodiment is not limited thereto.

In the electron transport regions ETR1, ETR2, ETR3 and ETR4, the foregoing compounds of the electron transport region may be included in the electron injection layer or the electron transport layer. In a case in which the electron transport regions ETR1, ETR2, ETR3 and ETR4 include the electron-side additional layer, and the electron-side additional layer may include the foregoing material. In an embodiment, the fourth electron injection layer EIL4 may include two or more materials selected from Mg, Ag, Yb, and Al. The fourth electron injection layer EIL4 may include, for example, a mixture of Mg and Yb.

Each of the electron transport regions ETR1, ETR2, ETR3 and ETR4 may have a thickness of, for example, about 10 nm to about 150 nm. The electron transport layer may have a thickness of about 0.1 nm to about 100 nm, for example, a thickness of about 0.3 nm to 50 nm. In case that the thickness of the electron transport layer satisfies the foregoing range, satisfactory electron transport properties may be obtained without a substantial increase in driving voltage.

The second electrode CE may be provided (or disposed) on the emission structures ST1, ST2, ST3 and ST4. The second electrode CE may be a common electrode. The second electrode CE may be a cathode or an anode, but an embodiment is not limited thereto. For example, in a case in which the first electrode AE is an anode, the second electrode CE may be a cathode, and in a case in which the first electrode AE is a cathode, the second electrode CE may be an anode.

The second electrode EL2 may be a semi-transmissive electrode or a transmissive electrode. In a case in which the second electrode CE is a transmissive electrode, the second electrode CE may include a transparent metal oxide, for example, an indium tin oxide (ITO), an indium zinc oxide (IZO), a zinc oxide (ZnO), an indium tin zinc oxide (ITZO), or the like.

In a case in which the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, In, Zn, Sn, or a compound or mixture thereof (e.g., AgMg, AgYb, or MgAg). In another example, the second electrode CE may have a multilayer structure including a reflective film or a semi-transmissive film, each of which is made of the foregoing material, and a transparent conductive film made of an indium tin oxide (ITO), an indium zinc oxide (IZO), a zinc oxide (ZnO), an indium tin zinc oxide (ITZO) or the like. For example, the second electrode CE may include the foregoing metal material, a combination of two or more metal materials selected from the foregoing metal materials, an oxide of the foregoing metal materials, or the like. As an example, FIG. 5 illustrates the emission unit EML including the first to fourth emission structures ST1, ST2, ST3 and ST4, but the emission structures are not limited thereto as long as the entirety of the emission unit EML is not disposed as a common layer.

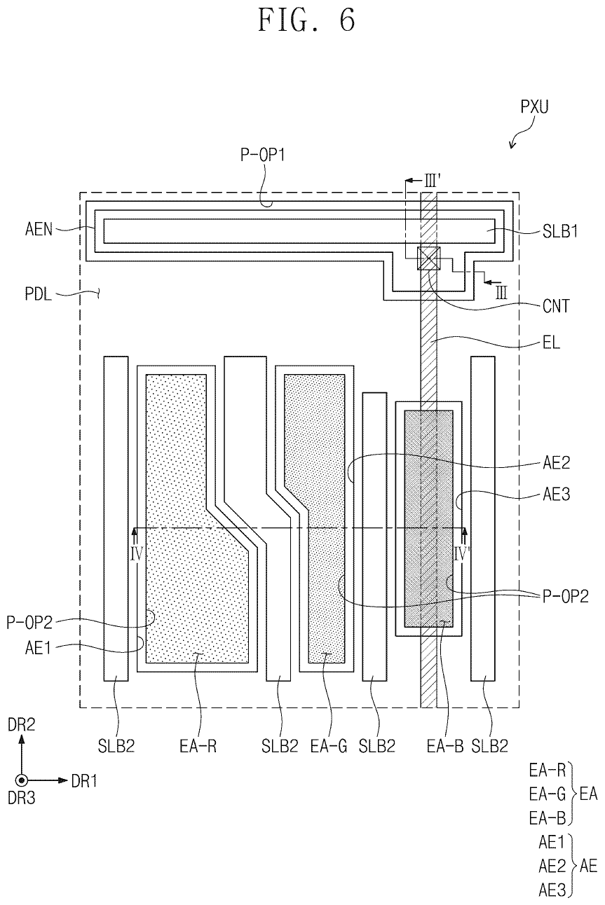

FIG. 6 is a schematic plan view corresponding to a pixel unit PXU of a display panel DP according to an embodiment.

FIG. 6 illustrates, in more detail, components disposed in the display panel DP based on the pixel unit PXU illustrated in FIG. 3. FIG. 6 illustrates first electrodes AE1, AE2 and AE3 disposed to correspond to (or to overlap) first to third emission areas EA-R, EA-G and EA-B, respectively, a connection electrode AEN spaced apart from the first to third emission areas EA-R, EA-G and EA-B in the second direction DR2, a power line EL, a contact hole CNT overlapping the connection electrode AEN and the power line EL, a first separator SLB1, and a second separator SLB2.

Referring to FIG. 6, the connection electrode AEN may overlap the power line EL. The connection electrode AEN may intersect a line portion, which extends in the second direction DR2, of the power line EL, and the connection electrode AEN may extend in the first direction DR1.

The first separator SLB1 may be disposed on the connection electrode AEN. The first separator SLB1 may have a smaller surface area than the connection electrode AEN. As an example, FIG. 6 illustrates the first separator SLB1 disposed inside the connection electrode AEN, but an embodiment is not limited thereto.

Referring to FIG. 6, the second separator SLB2 may be disposed to be spaced apart from the first separator SLB1. The second separator SLB2 may be disposed between emission areas adjacent to each other in the first direction DR1 among the first to third emission areas EA-R, EA-G and EA-B, and each of the second separators SLB2 may have a shape extending in the second direction DR2. As an example, four second separators SLB2 are illustrated which are disposed to respectively correspond to (or to overlap) a space between the first emission area EA-R and the second emission area EA-G, a space between the second emission area EA-G and the third emission area EA-B, a side (or single side) of the first emission area EA-R, and a side (or single side) of the third emission area EA-B, and which are spaced apart from each other. The second separator SLB2 may be sufficient as long as having a length to separate adjacent emission areas from each other among different emission areas.

FIG. 6 illustrates examples of respective planar shapes of the first and second separators SLB1 and SLB2, and an embodiment is not limited thereto. The planar shapes of the separators may be changed according to planer shapes of the emission areas, an arrangement shape of the emission areas, an arrangement gap between the emission areas, and the like.

FIG. 7 is a schematic cross-sectional view of a portion of a display device DD according to an embodiment. FIG. 7 may correspond to a cross-section of the display device DD taken along line III-III′ in FIG. 6. Hereinafter, an electrical connection structure of a power line EL and a second electrode CE will be described in detail with reference to FIGS. 6 and 7.

Referring to FIGS. 6 and 7, the power line EL may be disposed to overlap a non-pixel area NPXA. The power line EL may be disposed to be spaced apart from the gate G-D (see FIG. 4), and be disposed on the same layer as the gate G-D. The power line EL and the gate G-D may be formed using the same material and through the same process. The power line EL may be disposed on a first insulating layer 10.

FIG. 7 illustrates the power line EL having a single-layer structure, but the power line EL may have a structure in which multiple layers are stacked. The power line EL may be made of a metal material. For example, the power line EL may be made of any one of molybdenum (Mo), aluminum (Al), chromium (Cr), gold (Au), titanium (Ti), nickel (Ni), neodymium (Nd), copper (Cu), and an indium tin oxide (ITO), or made of an alloy thereof.

A second insulating layer 20 may cover the power line EL that is patterned. A third insulating layer 30 may be disposed on the second insulating layer 20.

A connection electrode AEN may be disposed on the third insulating layer 30. The connection electrode AEN may be formed through the same process and include the same material as the first electrodes AE1, AE2 and AE3 in FIG. 6.

The connection electrode AEN may be connected to the power line EL through a contact hole CNT defined in the first to third insulating layers 10, 20 and 30. A portion of an emission unit EML and a portion of the second electrode CE may be disposed inside the contact hole CNT.

A pixel defining film PDL may be disposed on the third insulating layer 30, and the connection electrode AEN may be exposed (e.g., entirely exposed) by an opening portion P-OP1 of the pixel defining film PDL. For example, the entirety of the connection electrode AEN may be disposed within the opening portion P-OP1 overlapping the non-pixel area NPXA. A width of the opening portion P-OP1 in the second direction DR2 may be greater than a width of the connection electrode AEN in the second direction DR2.

A first separator SLB1 may be disposed on the connection electrode AEN. The first separator SLB1 may have an undercut shape. The first separator SLB1 may include two side surfaces facing each other in the second direction DR2. The first separator SLB1 may have a first portion S1 (or a first area) of the side surface of the first separator SLB1 and a second portion S2 (or a second area) of the side surface of the first separator SLB1. A distance between the first portions S1 of the two side surfaces may be uniform, and a distance between the second portions S2 of the two side surfaces may gradually increase as being away from the third insulating layer 30 in the third direction DR3.

The first separator SLB1 may include a first portion PT1 of the first separator SLB1, which is in contact with the connection electrode AEN, and a second portion PT2 of the first separator SLB1 which is disposed on the first portion PT1. The first portion PT1 may include the first portion S1 of the side surface described above, and the second portion PT2 may correspond to (or overlap) the second portion S2 of the side surface described above. A width of the second portion PT2 in a direction (e.g., the second direction DR2) may be greater than a width of the first portion PT1 in the direction (e.g., the second direction DR2). The first portion PT1 and the second portion PT2 may have a shape of a single body.

The emission unit EML may be disposed on the third insulating layer 30 and the pixel defining film PDL. The emission unit EML may be formed through deposition, and during this process, the emission unit EML may be cut by the first separator SLB1. The first separator SLB1 may cut at least one of the emission structures ST1, ST2, ST3 and ST4 and at least one of the charge generation layers CGL1, CGL2 and CGL3, which are described with reference to FIG. 5. The emission unit EML may have an end portion in an area adjacent to the first separator SLB1. As the emission unit EML is cut by the first separator SLB1, current flow (hereinafter referred to as leakage current) between adjacent emission areas through the emission unit EML may be disconnected.

During the deposition of the emission unit EML, a portion of a light emitting material may be deposited onto a top surface (or upper surface) of the first separator SLB1. This formed material may be defined as a first dummy pattern DMY1.

The second electrode CE may be disposed on the emission unit EML. A vacuum deposition method may be used to form the second electrode CE on the emission unit EML. For example, the second electrode CE may be also cut by the first separator SLB1.

The second electrode CE may be formed through conformal deposition. Unlike the emission unit EML, the second electrode CE may be deposited using a conformal deposition method to extend up to a lower undercut space.

The second electrode CE formed through the foregoing deposition method may be connected to (i.e., in contact with) the connection electrode AEN despite the emission unit EML disposed below the second electrode CE. A portion of the second electrode CE, which is disposed relatively adjacent to the first separator SLB1 beyond the emission unit EML, i.e., a portion, which is in contact with the connection electrode AEN, of a cut portion of the second electrode CE, may be defined as a contact portion CTP.

The contact portion CTP may overlap the first separator SLB1 in a plan view. The second electrode CE may cover an end portion of the emission unit EML, which is adjacent to the first separator SLB1, among end portions of the emission unit EML. Due to the first separator SLB1, the contact portion CTP of the second electrode CE may overlap the second portion PT2 in a direction (e.g., the third direction DR3). The contact portion CTP of the second electrode CE may be spaced apart from the first portion PT1 in the second direction DR2, and be in contact with the connection electrode AEN.

The second electrode CE and the power line EL may be connected to each other without requiring an additional process to contact between the second electrode CE and the power line EL. The second electrode CE may be electrically connected to the power line EL, and thus voltage drop of the second electrode CE may be prevented.

During the deposition of the second electrode CE, a portion of an electrode material may be deposited onto the top surface (or upper surface) of the first separator SLB1. This formed material may be defined as a second dummy pattern DMY2. A portion of the second dummy pattern DMY2 may be disposed on the first dummy pattern DMY1.

The second dummy pattern DMY2 formed through the foregoing deposition method may be also disposed on the first portion S1 and the second portion S2 of the first separator SLB1. The second dummy pattern DMY2 may cover the second portion S2 of the side surface of the first separator SLB1.

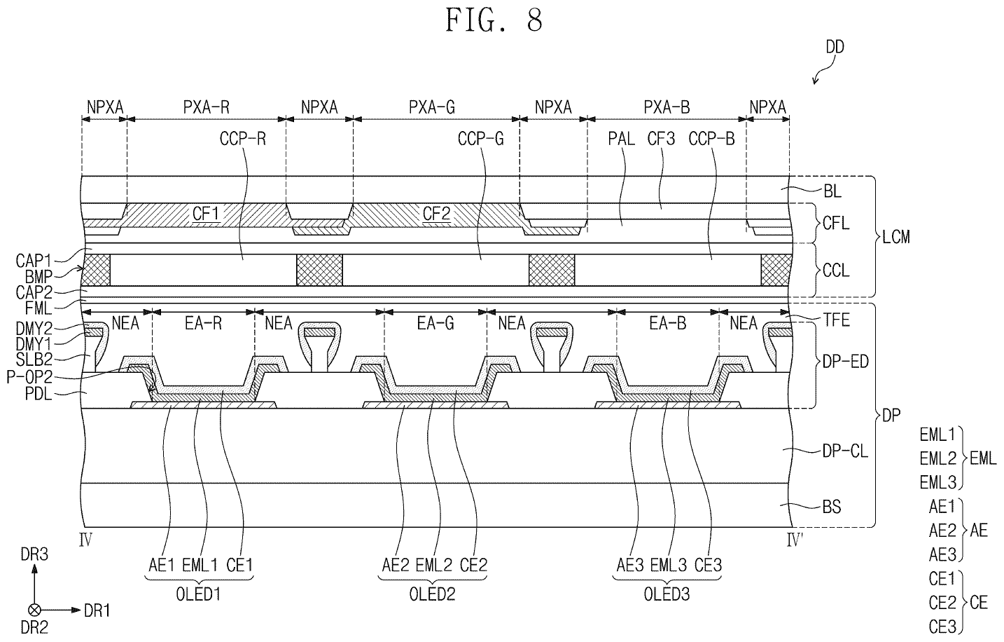

FIG. 8 is a schematic cross-sectional view illustrating a portion of a display device DD according to an embodiment. FIG. 8 may correspond to a cross-section of the display device DD taken along line IV-IV′ illustrated in FIG. 6. Hereinafter, a second separator SLB2 will be described in more detail with reference to FIGS. 6 and 8.

Referring to FIGS. 6 and 8, the second separator SLB2 may overlap a non-emission area NEA and may be disposed on a pixel defining film PDL. The second separator SLB2 may be in contact with (e.g., in direct contact with) a top surface (or upper surface) of the pixel defining film PDL. The first separator SLB1 and the second separator SLB2 may be formed through the same process described above.

The second separator SLB2 may be disposed between a first emission area EA-R and a second emission area EA-G and cut an emission unit EML between a first light emitting element OLED1 and a second light emitting element OLED2. The second separator SLB2 may be disposed between the second emission area EA-G and a third emission area EA-B and cut the emission unit EML between the second light emitting element OLED2 and a third light emitting element OLED3.

Even though a portion of the emission unit EML is cut by the second separator SLB2 during the formation of the emission unit EML, the emission unit EML may have a shape of one body at a portion in which the second separator SLB2 is not disposed on a plane. Due to the cut structure of the emission unit EML, movement of charges to neighboring emission areas by the charge generation layers CGL1, CGL2 and CGL3 (see FIG. 5) may be blocked.

The second separator SLB2 may be provided to sufficiently prevent contact between respective side surfaces of adjacent emission areas among the emission areas EA-R, EA-G and EA-B arranged in the first direction DR1, and also, as being disposed to correspond to (or to overlap) each of spaces between the emission areas EA-R, EA-G and EA-B, the second separator SLB2 may cut at least a portion of components, which are provided as common layers to the emission areas EA-R, EA-G and EA-B, of the first, second, and third light emitting elements OLED1, OLED2 and OLED3. Accordingly, charges or excitons in the emission unit EML may be prevented from being transferred to adjacent pixel areas, thereby reducing leakage emission to emission areas adjacent in the first direction DR1.

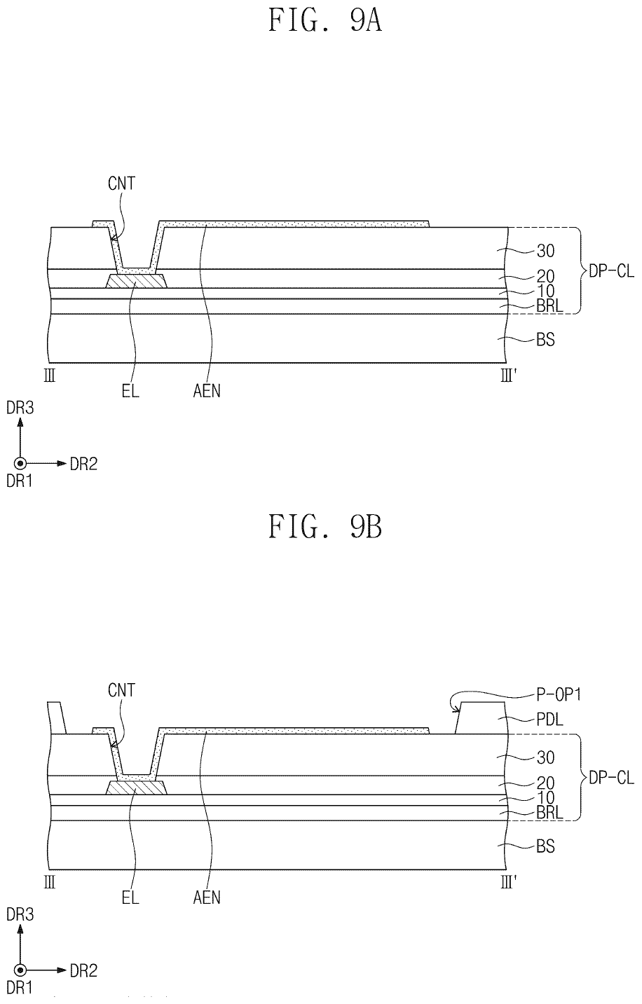

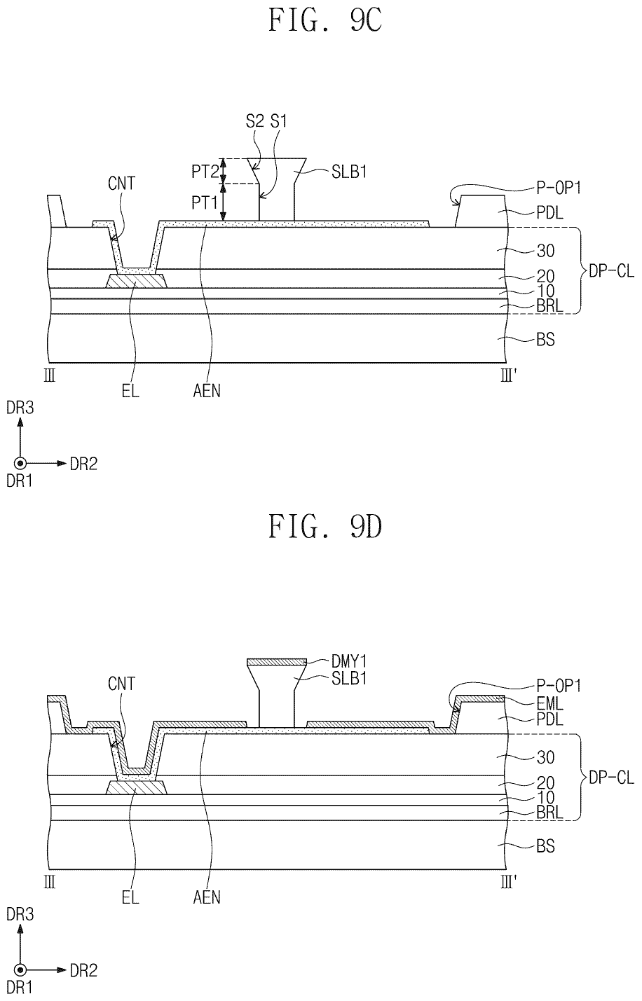

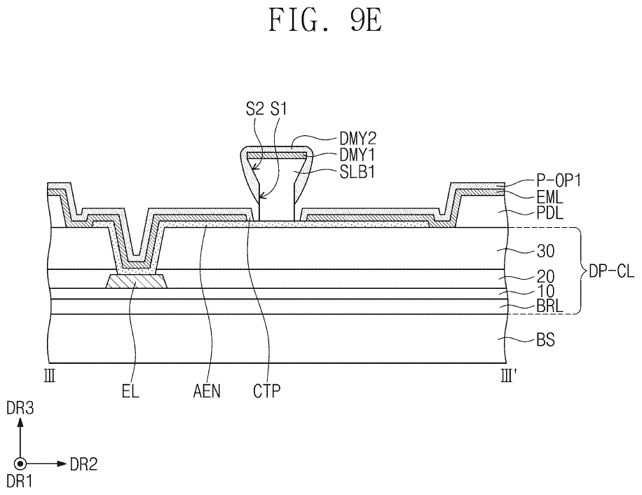

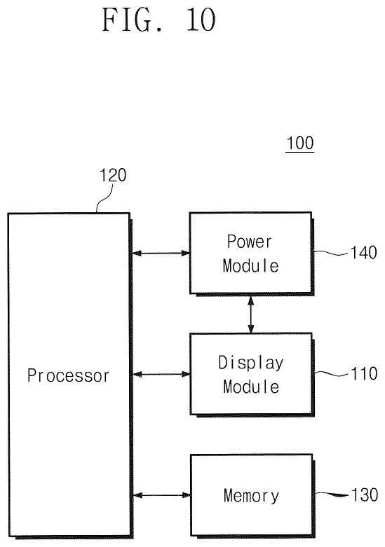

FIGS. 9A, 9B, 9C, 9D, and 9E are each a schematic cross-sectional view illustrating a portion of a method for manufacturing a display device DD according to an embodiment.

Referring to FIG. 9A, the method for manufacturing the display device DD may include forming a power line EL on a base substrate BS. The power line EL may be formed using a photolithography process. For example, the power line EL may be formed on a first insulating layer 10. Thereafter, a second insulating layer 20 and a third insulating layer 30 may be formed. The first insulating layer 10, the second insulating layer 20, and the third insulating layer 30, described above, may be formed through a deposition process or a coating process.

Thereafter, a connection electrode AEN may be formed on the third insulating layer 30. A contact hole CNT passing through the second insulating layer 20 and the third insulating layer 30 may be formed, and then the connection electrode AEN connected to the power line EL may be formed through the photolithography process.

The method for manufacturing the display device DD according to this embodiment may further include forming, on the base substrate BS, the first electrode AE described with reference to FIG. 7. In this embodiment, the connection electrode AEN and the first electrode AE may be performed through the same process.

Referring to FIG. 9B, the method for manufacturing the display device DD may include forming a pixel defining film PDL including an opening portion P-OP1 overlapping a non-pixel area NPXA. An insulating layer overlapping the non-pixel area NPXA may be formed, and then the opening portion P-OP1 may be formed through the photolithography process. The opening portion P-OP1 may expose at least a portion of the connection electrode AEN.

The method for manufacturing the display device DD according to this embodiment may further include forming the emission opening portion P-OP2 described with reference to FIG. 7. In an embodiment, the emission opening portion P-OP2 and the opening portion P-OP1 may be formed through the same process.

Referring to FIG. 9C, the method for manufacturing the display device DD may include forming a first separator SLB1 on the connection electrode AEN. A negative-type organic photosensitive material may be used to be exposed and developed to form the first separator SLB1 through the photolithography process. As the material constituting the first separator SLB1 is an organic material, through the process of exposing the material using a mask, a top surface (or upper surface) of the first separator SLB1 may have a small exposed portion due to a large amount of transmitted light, and a bottom surface (or lower surface) of the first separator SLB1 may have a large exposed portion due to a relatively small amount of the transmitted light, so that a reverse tapered shape may be formed.

Referring to FIG. 9D, the method for manufacturing the display device DD may include forming an emission unit EML overlapping the connection electrode AEN, the pixel defining film PDL, and the first separator SLB1. The emission unit EML may be disposed on the connection electrode AEN to overlap the connection electrode AEN.

A portion of the emission unit EML may be disposed on the connection electrode AEN, and the remaining portion thereof may be disposed on the pixel defining film PDL. For example, a portion of the emission unit EML may be disposed in the opening portion P-OP1 of the pixel defining film PDL, and the remaining portion thereof may be disposed on the pixel defining film PDL.

The forming of the emission unit EML may include depositing a material constituting the emission unit EML in a direction (e.g., the third direction DR3) parallel to a thickness direction of the base substrate BS. The depositing of the emission unit EML may include depositing the material constituting the emission unit EML in the third direction DR3 perpendicular to the base substrate BS. During the depositing of the material constituting the emission unit EML in the third direction DR3, the emission unit EML may be cut by the first separator SLB1.

As the emission unit EML is deposited in the direction parallel to the third direction DR3, a portion of the emission unit EML may be formed on the first separator SLB1, and the remaining portion may be formed on the connection electrode AEN and the pixel defining film PDL. A first dummy pattern DMY1 may be patterned by the first separator SLB1. The first dummy pattern DMY1 and the emission unit EML may be formed through the same process. The first dummy pattern DMY1 may not be deposited on a side surface of the first separator SLB1, but deposited on a top surface (or upper surface) of the first separator SLB1.

Referring to FIG. 9E, the method for manufacturing the display device DD may include forming a second electrode CE overlapping the connection electrode AEN, the pixel defining film PDL, and the first separator SLB1. The second electrode CE may be formed on the emission unit EML.

In the second electrode CE, due to the first separator SLB1, a portion of the second electrode CE may be formed on the first separator SLB1, and the remaining portion of the second electrode CE may be formed on the emission unit EML. The second electrode CE disposed on the first separator SLB1 may be a second dummy pattern DMY2. The second dummy pattern DMY2 may be disposed on the first dummy pattern DMY1. The second dummy pattern DMY2 and the second electrode CE may be formed through the same process.

The second electrode CE may be formed on the emission unit EML in a direction having a certain angle to the thickness direction (e.g., the third direction DR3) of the base substrate BS. In the forming of the second electrode CE, as the portion of the second electrode CE is formed on the first separator SLB1, and the remaining portion of the second electrode CE is formed on the emission unit EML, a portion of the second electrode CE may be cut by the first separator SLB1. A cut portion CTP of the second electrode CE, i.e., a contact portion CTP of the second electrode CE, may be in contact with the connection electrode AEN. For example, the second electrode CE may cover an end portion of the emission unit EML, which is adjacent to the first separator SLB1, among end portions of the emission unit EML. For example, the cut portion CTP of the second electrode CE may overlap the first separator SLB1 in the third direction DR3. As the second electrode CE is in contact with the connection electrode AEN, the second electrode CE may receive an electrical signal of the power line EL which is transmitted to the connection electrode AEN.

The second electrode CE may be in contact with (e.g., in direct contact with) the connection electrode AEN at a lower portion of the first separator SLB1 and receive a signal of the power line EL, thereby omitting a process of removing a portion of each of the emission unit EML and a circuit element layer DP-CL to form a contact hole by using a laser drilling method. For example, in a typical process of forming a contact hole performed in the order of depositing the emission unit EML, removing the portion of each of the emission unit EML and the circuit element layer DP-CL using the laser drilling method so as to expose the power line EL, and then depositing the second electrode CE so as to cover the emission unit EML and the power line EL exposed in the contact hole, the process of forming the contact hole using the laser drilling method may be omitted, and processes such as deposition, masking, and etching used in formation of the circuit element layer DP-CL and a display element layer DP-ED may be used as they are, so that the second electrode CE and the power line EL may be in contact with each other. Accordingly, the laser drilling process introduced (or permeated) between the deposition of the emission unit EML and the deposition of the second electrode CE may be omitted to increase process productivity and process efficiency.

As described above, the second electrode may be in contact with (e.g., in direct contact with) the connection electrode exposed at the lower undercut portion of the first separator and thus be connected to the power line. The second electrode may be electrically connected to the power line, thereby preventing the voltage drop of the second electrode. The laser drilling process may be omitted, thereby increasing the process productivity and the process efficiency.

The second separator may be disposed in the space between the emission areas, and thus cut the at least a portion of the components of the emission unit which are provided as the common layers to the emission areas. Accordingly, the leakage current between the emission areas may be reduced. Therefore, each of the emission areas may provide the light having the luminance corresponding to the desired gradation.

FIG. 10 is a block diagram of an electronic device according to an embodiment.

Referring to FIG. 10, an electronic device 100 according to an embodiment may include a display module 110, a processor 120, a memory 130, and a power module 140. The electronic device 100 may be at least one of a smart watch, a mobile phone, a smartphone, a portable computer, a tablet personal computer (PC), a watch phone, an automotive display, a smart glass, a portable multimedia player (PMP), a navigation system, an ultra mobile computer (UMPC), a head mounted display (HMD) device, a virtual reality (VR) device, a mixed reality (MR) device, and an augmented reality (AR) device.

The processor 120 may include at least one of a central processing unit (CPU), an application processor (AP), a graphic processing unit (GPU), a communication processor (CP), an image signal processor (ISP), and a controller.

Data information required for operations of the processor 120 or the display module 110 may be stored in the memory 150. In case that the processor 120 executes an application stored in the memory 150, an image data signal and/or an input control signal may be transmitted to the display module 110, and the display module 110 may process the received signal and output image information through a display screen.

The power module 140 may include a power supply module such as a power adapter or a battery device and a power conversion module that converts power supplied by the power supply module to generate power required for the operation of the electronic device 100.

At least one of the components of the electronic device 100 may be included in the display device DD according to an embodiment. Further, some of individual modules functionally included inside one module may be included inside the display device DD, and the others thereof may be provided separately from the display device. For example, the display device DD may include the display module 110, and the processor 120, the memory 130, and the power module 140 may be provided in the form of other devices in the electronic device 100 rather than the display device DD.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation

What is claimed is:

1. An electronic device for provide an image, the electronic device comprising:
a display device comprising:
a base substrate;
a circuit element layer disposed on the base substrate and comprising a power line that receives a power voltage; and
a display element layer disposed on the circuit element layer, and comprising an emission area and a non-emission area adjacent to the emission area,
wherein the display element layer comprises:
a pixel defining film comprising:
an emission opening portion overlapping the emission area, and
an opening portion overlapping the non-emission area;
a connection electrode overlapping the non-emission area, comprising at least a portion exposed by the opening portion, and electrically connected to the power line;
a light emitting element comprising:
a first electrode having at least a portion exposed by the emission opening portion,
an emission unit disposed on the first electrode, and
a second electrode disposed on the emission unit and overlapping the emission area and the non-emission area; and
a first separator disposed on the connection electrode and that cuts the second electrode,
a portion of the second electrode, which is cut by the first separator, is in contact with the connection electrode in the non-emission area.

2. The electronic device of claim 1, wherein
the circuit element layer further comprises an insulating layer disposed on the power line, and
the connection electrode is connected to the power line through a contact hole defined in the insulating layer.

3. The electronic device of claim 1, wherein the portion of the second electrode, which is cut by the first separator, overlaps the first separator in a plan view.

4. The electronic device of claim 1, wherein the opening portion entirely exposes the connection electrode.

5. The electronic device of claim 1, wherein the first separator has an undercut shape.

6. The electronic device of claim 1, wherein
the first separator comprises a first portion, and a second portion disposed below the first portion and in contact with the connection electrode, and
a width of the first portion in a direction is greater than a width of the second portion in the direction.

7. The electronic device of claim 1, further comprising:
a first dummy pattern disposed on the first separator; and
a second dummy pattern disposed on the first dummy pattern, wherein
the first dummy pattern and the emission unit comprise a same material, and
the second dummy pattern and the second electrode comprise a same material.

8. The electronic device of claim 7, wherein
the emission unit overlaps the emission area and the non-emission area, and
a portion of the emission unit is disposed between the connection electrode and the second electrode in the non-emission area.

9. The electronic device of claim 1, further comprising:
a first dummy pattern disposed on the first separator; and
a second dummy pattern disposed on the first dummy pattern, wherein
the first separator comprises a first portion, and a second portion disposed below the first portion and in contact with the connection electrode, and
the second dummy pattern covers a first side surface of the first separator, which defines the first portion.

10. The electronic device of claim 9, wherein the second dummy pattern further covers a portion of a second side surface of the first separator, which defines the second portion.

11. The electronic device of claim 1, wherein
the first separator comprises a first portion, and a second portion disposed below the first portion and in contact with the connection electrode,
a width of the first portion in a direction is greater than a width of the second portion in the direction, and
the portion of the second electrode, which is cut by the first separator, overlaps the first portion and is spaced apart from the second portion in the direction, and is in contact with the connection electrode.

12. The electronic device of claim 11, wherein the first portion and the second portion have a shape of one body.

13. The electronic device of claim 1, further comprising:
a second separator disposed to be spaced apart from the first separator in a plan view, wherein
the emission unit overlaps the emission area and the non-emission area,
the light emitting element comprises a first light emitting element, and a second light emitting element spaced apart from the first light emitting element in a direction, and
the second separator is disposed between the first light emitting element and the second light emitting element and cuts the emission unit in the non-emission area.

14. The electronic device of claim 1, wherein the emission unit comprises:
a first emission structure, a second emission structure, a third emission structure, and a fourth emission structure, each of which comprises an emission layer and which are stacked in a thickness direction; and
first, second, and third charge generation layers, each of which is disposed between adjacent emission structures among the first emission structure, the second emission structure, the third emission structure, and the fourth emission structure.

15. The electronic device of claim 14, wherein at least one of the first emission structure, the second emission structure, the third emission structure, or the fourth emission structure, and at least one of the first, second, or third charge generation layer are cut by the first separator.

16. A method for manufacturing a display device, the method comprising:
forming a power line on a base substrate;
forming a connection electrode electrically connected to the power line on the base substrate;
forming a first electrode on the base substrate;
forming a pixel defining film comprising an opening portion, which exposes at least a portion of the connection electrode, and an emission opening portion which exposes at least a portion of the first electrode;
forming a separator on the connection electrode;
forming an emission unit overlapping the first electrode, the connection electrode, the pixel defining film, and the separator; and
forming a second electrode overlapping the first electrode, the connection electrode, the pixel defining film, and the separator, wherein
the emission unit is cut by the separator,
the second electrode is cut by the separator, and
a portion of the second electrode, which is cut by the separator, is in contact with the connection electrode.

17. The method of claim 16, wherein the connection electrode and the first electrode are formed through a same process.

18. The method of claim 16, wherein the portion of the second electrode, which is cut, overlaps the separator.

19. The method of claim 16, wherein, in the forming of the separator, a first portion and a second portion having a shape of one body together with the first portion are formed, and
a width of the first portion in a direction is formed to be greater than a width of the second portion in the direction.

20. The method of claim 16, wherein, in the forming of the separator, a first dummy pattern patterned by the separator and a second dummy pattern disposed on the first dummy pattern are formed, and
the first dummy pattern and the emission unit are formed through a same process, and
the second dummy pattern and the second electrode are formed through a same process.
